(19) United States
(12) Patent Application Publication
(10) Pub. No.: US 2023/0187317 A1
(43) Pub. Date: Jun. 15, 2023

(54) INTERCONNECT STRUCTURES

(71) Applicant: ADEIA SEMICONDUCTOR BONDING TECHNOLOGIES INC., San Jose, CA (US)

(72) Inventor: Cyprian Emeka Uzoh, San Jose, CA (US)

(21) Appl. No.: 18/064,815

(22) Filed: Dec. 12, 2022

Related U.S. Application Data
(60) Provisional application No. 63/288,991, filed on Dec. 13, 2021.

(51) Int. Cl. H01L 23/48; H01L 23/00; H01L 21/768; H01L 23/532

(52) U.S. Cl. CPC H01L 23/481; H01L 24/05; H01L 21/76898; H01L 21/76843; H01L 21/76807; H01L 23/53238; H01L 23/53257; H01L 2224/05647

(57) ABSTRACT

Disclosed is a semiconductor element including a semiconductor portion, a nonconductive layer on the semiconductor portion, an upper conductive layer formed of a first material and at least partially embedded in the nonconductive layer, a lower conductive layer below and electrically connected to the upper conductive layer, and a barrier layer disposed between the upper conductive layer and the lower conductive layer. The barrier layer is formed of a second material different from the first material, and the second material has an electrical resistivity less than 50×10⁻⁸ mΩ at 20° C. and a melting point greater than 1200° C.

### CROSS-REFERENCE TO RELATED APPLICATIONS

This application claims priority under 35 U.S.C. § 119(e) to U.S. Provisional Patent Application No. 63/288,991, filed Dec. 13, 2021, titled “INTERCONNECT STRUCTURES,” the entire contents of which are hereby incorporated by reference herein in their entirety and for all purposes.

### BACKGROUND

### Field

The field relates to interconnect structures, and methods for forming interconnect structures.

### Description of the Related Art

Interconnect structures within a die or at a surface of a die convey signals, power, or ground to other circuits within the die or to another die or element. For example, semiconductor elements, such as semiconductor wafers or integrated device dies, can be stacked and directly bonded to one another without an adhesive. For example, in some hybrid direct bonded structures, nonconductive field regions of the elements can be directly bonded to one another, and corresponding conductive contact structures can be directly bonded to one another. It can be important to ensure that the contact structures are electrically reliable.

### BRIEF DESCRIPTION OF THE DRAWINGS

The detailed description is set forth with reference to the accompanying figures. The use of the same reference numbers in different figures indicates similar or identical items.

For this discussion, the devices and systems illustrated in the figures are shown as having a multiplicity of components. Various implementations of devices and/or systems, as described herein, may include fewer components and remain within the scope of the disclosure. Alternatively, other implementations of devices and/or systems may include additional components, or various combinations of the described components, and remain within the scope of the disclosure.

These aspects and others will be apparent from the following description of preferred embodiments and the accompanying drawings, which are meant to illustrate and not to limit the invention, wherein:

FIG. 1A is a schematic side sectional view of two elements before being directly bonded, according to one embodiment.

FIG. 1B is a schematic side sectional view of the two elements from FIG. 1A after being directly bonded, according to one embodiment.

FIG. 2A is side sectional view from a microscope of a conventional interconnect, showing the consequences of electromigration.

FIG. 2B is a schematic side sectional view of a conventional interconnect, showing the consequences of electromigration according to this invention.

FIG. 3 is a schematic side sectional view of a portion of a semiconductor element, according to one embodiment.

FIG. 4A is a schematic side sectional view of a conventional interconnect before current flowing through it forms voids.

FIG. 4B is a schematic side sectional view of the conventional interconnect from FIG. 4A after voids have formed and increased the resistance through the circuit.

FIG. 4C is a schematic side sectional view of a semiconductor element before current flowing through it, according to one embodiment.

FIG. 4D is a schematic side sectional view of the semiconductor element from FIG. 4C illustrating current flow, using redundant pathways to flow to suppress void formation.

FIG. 5A is a schematic side sectional view of a bonded structure containing dual damascene features, according to one embodiment.

FIG. 5B is a schematic side sectional view of a bonded structure containing single and dual damascene features, according to one embodiment.

FIG. 5C is a schematic side sectional view of a bonded structure containing single damascene features, according to one embodiment.

FIG. 6 is a schematic side sectional view of the layering between a dielectric layer, a low-resistance barrier layer, and a conductive layer, according to one embodiment.

FIGS. 7A-7H present a series of schematic side sectional views that show a multi-step method by which a conventional interconnect can be formed.

FIGS. 8A-8K present a series of schematic side sectional views that show a multi-step method by which a bonded structure can be formed, according to one embodiment.

FIGS. 9A-9E present a series of schematic side sectional views that show a multi-step method by which a semiconductor element can be formed to have lower, intermediate, and upper conductive layers, according to one embodiment.

FIG. 10 is a schematic side sectional view of a semiconductor element, according to one embodiment.

FIG. 11 is a schematic side sectional view of a bonded structure formed by bonding two semiconductor elements like the one shown in FIG. 9E, according to one embodiment.

FIG. 12 is a schematic side sectional view of a bonded structure formed by bonding two semiconductor elements like the one shown in FIG. 10, according to one embodiment.

FIGS. 13A-13D present a series of schematic side sectional views that show a multi-step method by which a semiconductor element can be formed with the use of a plasma treatment, according to one embodiment.

FIG. 14A is a schematic side sectional view of a semiconductor element, according to one embodiment.

FIG. 14B is a schematic side sectional view of a bonded structure formed by bonding two semiconductor elements like the one shown in FIG. 14A.

FIG. 14C is a schematic side sectional view of a semiconductor element, according to one embodiment.

FIG. 14D is a schematic side sectional view of a bonded structure formed by bonding two semiconductor elements like the one shown in FIG. 14C.

FIG. 15A is a schematic side sectional view of a bonded structure formed by direct hybrid bonding two semiconductor elements, in which one semiconductor element has a through-substrate via (TSV), according to one embodiment.

FIG. 15B is a schematic side sectional view of a bonded structure formed by direct hybrid bonding two semiconductor elements, in which one semiconductor element has a through-substrate via (TSV), according to one embodiment.

FIG. 16 is a schematic side sectional view of a semiconductor element that includes an inner manganese barrier layer, according to one embodiment.

FIG. 17A is a schematic side sectional view of a bonded structure formed by bonding two semiconductor elements, in which one semiconductor element has a through-substrate via (TSV), according to one embodiment.

FIG. 17B is a schematic side sectional view of a bonded structure formed by bonding two semiconductor elements, according to one embodiment.

FIG. 17C is a schematic side sectional view of a semiconductor element that includes both an inner manganese barrier layer and a through-substrate via (TSV), according to one embodiment.

### DETAILED DESCRIPTION

Metal interconnect structures are susceptible to electromigration and/or other diffusion effects. For example, electromigration can occur in metallization or interconnect layers (for example, those comprising copper) within a bonding layer of a semiconductor element, in interconnects in back-end-of line (BEOL) layers of an integrated device die, in interconnects in a redistribution layer (RDL), or in any other metallization layers with interconnects including contact structures in which there is a transition between metallization layers of different resistivity or different cross-sectional sizes (e.g., between layers buried in a BEOL stack, or within a bonding layer of a semiconductor element to be direct hybrid bonded).

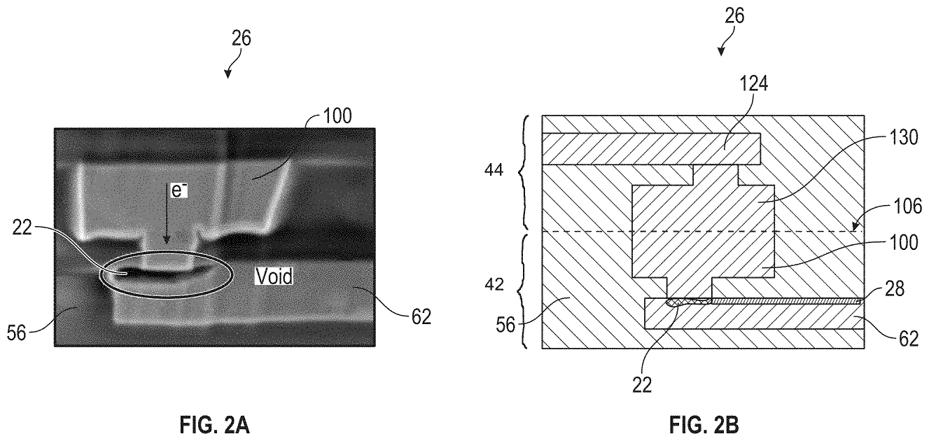

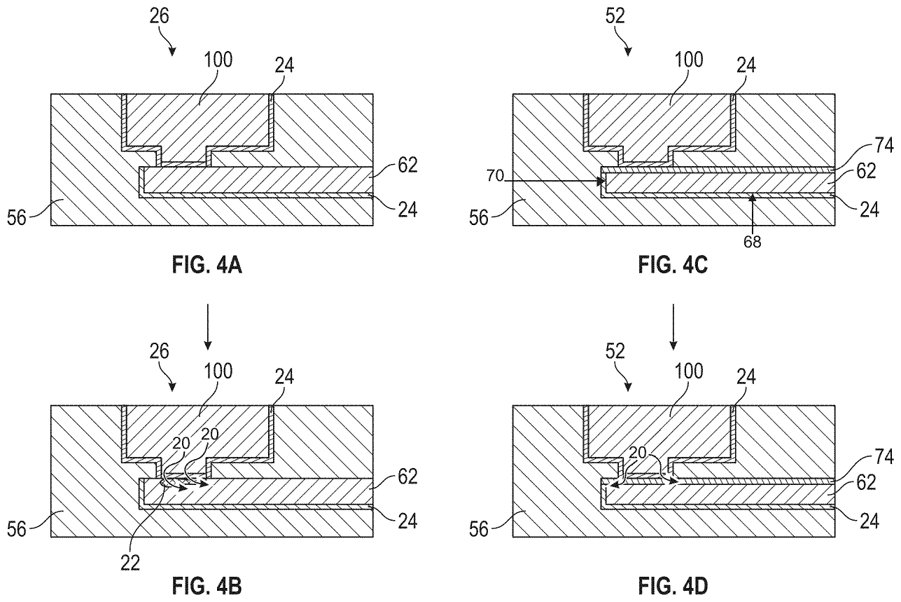

Electromigration is a phenomenon in which metal atoms within a conductive path of a circuit are induced to move in the direction of the electron flow. This can be caused by the momentum transfer from electrons to the metal atoms as the electrons flow along the conductive path of the circuit. This movement of metal atoms in the direction of electron flow is sometimes referred to as the atoms being influenced by “electron wind.” Electromigration can cause circuit failure either by creating a short circuit “downwind” or by creating an open circuit “upwind”. Electromigration can cause a short circuit “downwind” because it is possible that the metal atoms that move in the direction of electron flow will be pushed beyond the intended conductive path, which can lead to the creation of a metal whisker that can electrically connect with a circuit component to which it was not designed to electrically connect. And electromigration can cause an open circuit “upwind” because if too many metal atoms migrate in the direction of electron flow, there may not be enough metal atoms left “upwind” to keep the circuit intact. When a metal atom migrates, it leaves a vacancy where it once was, and a collection of vacancies can become a void (shown as 22 in FIGS. 2A-2B), and the presence of voids can impede the flow of electrons. The problems of electromigration get worse, for example, as temperature increases, as current density increases, and as interconnect sizes get smaller. Electromigration (e.g., current crowding) can also occur when current travels from a higher conductivity material (such as copper) to a lower conductivity material (such as a conventional barrier layer, shown as 24 in FIGS. 4A and 4B), and/or when travelling from a wider, more conductive path to a narrower, more resistive path.

Various embodiments disclosed herein can provide improved barrier layer(s) that have low electrical resistivity and high melting point, which can reduce electromigration and increase thermal stability as compared to interconnects without barrier layers or that include conventional barrier layers (shown as 24 in FIGS. 4A and 4B). Some embodiments disclosed herein relate to interconnects in a bonding layer (e.g., a layer configured for direct hybrid bonding) of an element, for example, contact structures and/or underlying metallization within the bonding layer in which there is a transition between metal levels. The embodiments disclosed herein may also reduce electromigration in metallization layers that are buried in other layers of a die, for example, in BEOL and RDL structures.

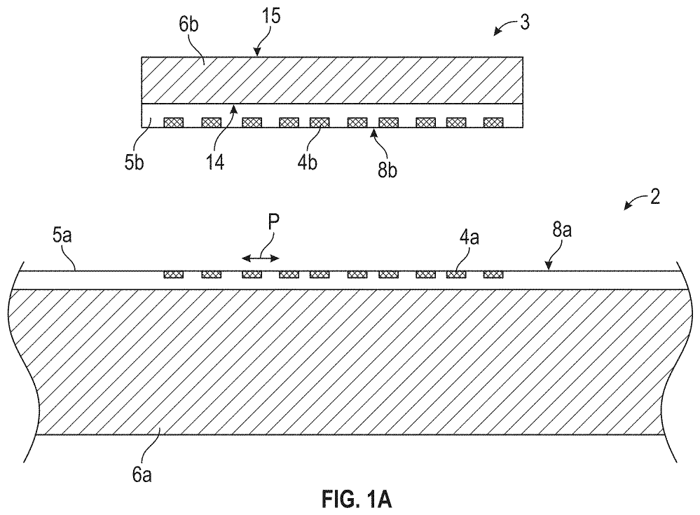

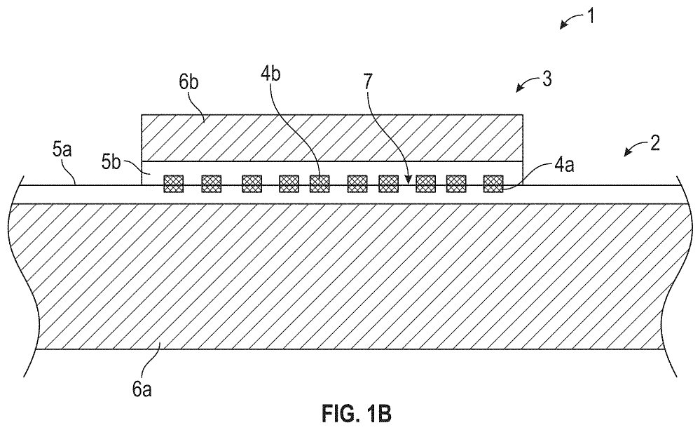

As shown in FIGS. 1A-1B, in some embodiments, the metallization solutions disclosed herein relate to bonding layers for directly bonded structures 1 in which a first element 2 and a second element 3 can be directly bonded to one another without an intervening adhesive. FIG. 1A illustrates elements 2, 3 before directly bonding. FIG. 1B illustrates the bonded structure 1 after directly bonding the elements 2, 3. Two or more semiconductor elements (such as integrated device dies, wafers, etc.) 2, 3 may be stacked on or bonded to one another to form a bonded structure 1. Conductive contact structures including contact pads 4a (pads, vias, trenches) of a first element 2 may be electrically connected to corresponding conductive contact pads 4b or other conductive contact structures (for example, pad to via, pad to trench, trench to trench, etc.) of a second element 3. Although only exposed contact pads 4a, 4b are shown in FIGS. 1A and 1B for purposes of illustrating direct bonding, the skilled artisan will appreciate that bonding layers may include multiple metal layers and routing with connections between the layers as illustrated in FIGS. 2A-17C. Any suitable number of elements can be stacked in the bonded structure 1. For example, a third element (not shown) can be stacked on the second element 3, a fourth element (not shown) can be stacked on the third element, etc. Inclusion of through-substrate vias (TSVs, not shown) can facilitate electrical connection for such further stacking. Additionally or alternatively, one or more additional elements (not shown) can be stacked laterally adjacent one another along the first element 2.

In some embodiments, the elements 2, 3 are directly bonded to one another without an adhesive. In various embodiments, a nonconductive or dielectric material can serve as a nonconductive bonding layer 5a of the first element 2 which can be directly bonded to a corresponding nonconductive or dielectric field region serving as a nonconductive bonding layer 5b of the second element 3 without an adhesive. The nonconductive bonding layers 5a, 5b can be disposed on respective front sides 14 of device portions 6a, 6b, such as a semiconductor (e.g., silicon) portion of the elements 2, 3. Active devices and/or circuitry can be patterned and/or otherwise disposed in or on the device portions 6a, 6b. Active devices and/or circuitry can be disposed at or near the front sides 14 of the device portions 6a, 6b, and/or at or near opposite back sides 15 of the device portions 6a, 6b. The nonconductive material can be referred to as a nonconductive bonding region or bonding layer 5a of the first element 2. In some embodiments, the nonconductive bonding layer 5a of the first element 2 can be directly bonded to the corresponding nonconductive bonding layer 5b of the second element 3 using dielectric-to-dielectric bonding techniques. For example, nonconductive or dielectric-to-dielectric bonds may be formed without an adhesive using the direct bonding techniques disclosed at least in U.S. Pat. Nos. 9,564,414; 9,391,143; and 10,434,749, the entire contents of each of which are incorporated by reference herein in their entirety and for all purposes. It should be appreciated that in various embodiment, the nonconductive bonding layers 5a and/or 5b can comprise a nonconductive material such as a dielectric material, such as silicon oxide, or an undoped semiconductor material, such as undoped silicon.

As shown in FIG. 1A, in various embodiments, bonding surfaces 8a, 8b comprise one or more nonconductive portions (e.g., the exposed surface of the nonconductive bonding layers 5a, 5b) and one or more conductive portions (e.g., the exposed surface of the contact pads 4a, 4b).

In various embodiments, direct hybrid bonds can be formed without an intervening adhesive. For example, nonconductive (e.g., dielectric) portion(s) of the bonding surfaces 8a, 8b can be polished to a high degree of smoothness. The nonconductive portion(s) of the bonding surfaces 8a, 8b can be cleaned and exposed to a plasma and/or etchants to be activated. In some embodiments, the nonconductive portion(s) of the bonding surfaces 8a, 8b can be terminated with a species after activation or during activation (e.g., during the plasma and/or etch processes). Without being limited by theory, in some embodiments, the activation process can be performed to break chemical bonds at the bonding surface 8a, 8b, and the termination process can provide additional chemical species at the bonding surface 8a, 8b that improves the bonding energy during direct bonding. In some embodiments, the activation and termination are provided in the same step, e.g., a plasma to activate and terminate the bonding surfaces 8a, 8b. In other embodiments, the bonding surfaces 8a, 8b can be terminated in a separate treatment to provide the additional species for direct bonding. In various embodiments, the terminating species can comprise nitrogen. Further, in some embodiments, the bonding surfaces 8a, 8b can be exposed to fluorine. For example, there may be one or multiple fluorine peaks near layer and/or bonding interfaces 7 (shown in FIG. 1B). Thus, in the directly bonded structure 1, the bonding interface 7 between nonconductive portions of two bonding surfaces 8a and 8b comprise a very smooth interface with higher nitrogen content and/or fluorine peaks at the bonding interface 7. In various embodiments, the nonconductive portions of the bonding surfaces 8a, 8b include the surface of nonconductive bonding layers 5a, 5b. Additional examples of activation and/or termination treatments may be found throughout U.S. Pat. Nos. 9,564,414; 9,391,143; and 10,434,749, the entire contents of each of which are incorporated by reference herein in their entirety and for all purposes.

In various embodiments, conductive contact pads 4a of the first element 2 can also be directly bonded to corresponding conductive contact pads 4b of the second element 3. For example, a hybrid bonding technique can be used to provide conductor-to-conductor direct bonds along the bonding interface 7 that includes covalently direct bonded nonconductive-to-nonconductive (e.g., dielectric-to-dielectric) surfaces, prepared as described above. In various embodiments, the nonconductive surfaces that are covalently direct bonded include exposed portions of the surfaces of nonconductive bonding layers 5a and 5b. In various embodiments, the conductor-to-conductor (e.g., contact pad 4a to contact pad 4b) direct bonds and the dielectric-to-dielectric hybrid bonds can be formed using the direct hybrid bonding techniques disclosed at least in U.S. Pat. Nos. 9,716,033 and 9,852,988, the entire contents of each of which are incorporated by reference herein in their entirety and for all purposes.

For example, the nonconductive (e.g., dielectric) portions of the bonding surfaces 8a, 8b can be prepared and directly bonded to one another without an intervening adhesive as explained above. Conductive contact pads 4a, 4b (which may be surrounded by nonconductive dielectric field regions within the bonding layers 5a, 5b) may also directly bond to one another without an intervening adhesive. In some embodiments, the respective contact pads 4a, 4b can be recessed below the exterior (e.g., upper) bonding surfaces 8a, 8b of the dielectric field or nonconductive bonding layers 5a, 5b, for example, recessed by less than 30 nm, less than 20 nm, less than 15 nm, or less than 10 nm, or for example, recessed in a range of 2 nm to 20 nm, or in a range of 4 nm to 10 nm. In various embodiments, prior to direct bonding, the recesses in the opposing elements 2, 3 can be sized such that the total gap between opposing contact pads 4a, 4b is less than 15 nm, or less than 10 nm. The nonconductive bonding layers 5a, 5b can be directly bonded to one another without an adhesive at room temperature and without the application of external pressure beyond that for contacting the bonding surfaces 8a, 8b in some embodiments and, subsequently, the bonded structure 1 can be annealed. Upon annealing, the contact pads 4a, 4b can expand and contact one another to form a metal-to-metal direct bond and complete the hybrid direct bonding process. Beneficially, the use of direct bonding and direct hybrid bonding processes as described above, including Direct Bond Interconnect, or DBI®, techniques commercially available from Adeia of San Jose, Calif., can enable high density of pads 4a, 4b connected across the direct bonding interface 7 (e.g., small or fine pitches for regular arrays). In some embodiments, the pitch p of the bonding pads 4a, 4b, or conductive traces embedded in the bonding surface 8a or 8b of one of the bonded elements, e.g., 2 or 3, may be less than 40 microns or less than 10 microns or even less than 2 microns. For some applications, the ratio of the pitch p of the bonding pads 4a, 4b to one of the dimensions (e.g., a diameter) of the bonding pad is less than 5, or less than 3 and sometimes desirably less than 2. In other applications the width of the conductive traces embedded in the bonding surface 8 of one of the bonded elements, e.g., 2 or 3, may range between 0.1 to 5 microns. In various embodiments, the contact pads 4a, 4b and/or traces can comprise copper, although other metals may be suitable.

Thus, in direct bonding processes, a first element 2 can be directly bonded to a second element 3 without an intervening adhesive. In some arrangements, the first element 2 can comprise a singulated element, such as a singulated integrated device die. In other arrangements, as shown in FIGS. 1A-1B, the first element 2 can comprise a carrier or substrate (e.g., a wafer) that includes a plurality (e.g., tens, hundreds, or more) of device regions that, when singulated, form a plurality of integrated device dies. Similarly, the second element 3 can comprise a singulated element, such as a singulated integrated device die, as shown in FIGS. 1A-1B. In other arrangements, the second element 3 can comprise a carrier or substrate (e.g., a wafer). The embodiments disclosed herein can accordingly apply to wafer-to-wafer, die-to-die, die-to-wafer, panel-to-panel, die-to-panel, or wafer-to-panel bonding processes.

As explained herein, the first and second elements 2, 3 can be directly bonded to one another without an adhesive, which is different from a deposition process. In one application, a width of the first element 2 in the bonded structure 1 is similar to a width of the second element 3. In some other embodiments, a width of the first element 2 in the bonded structure 1 is different from a width of the second element 3. Similarly, the width or area of the larger element in the bonded structure may be at least 10% larger than the width or area of the smaller element. The first and second elements 2, 3 can accordingly comprise non-deposited elements. Further, directly bonded structures 1, unlike deposited layers, can include a defect region along the bonding interface 7 in which nanovoids are present. The nanovoids may be formed due to activation of the bonding surfaces 8a, 8b (e.g., exposure to a plasma). As explained above, the bonding interface 7 can include concentration of materials from the activation and/or last chemical treatment processes. For example, in embodiments that utilize a nitrogen plasma for activation, a nitrogen peak can be formed at the bonding interface 7. In embodiments that utilize an oxygen plasma for activation, an oxygen peak can be formed at the bonding interface 7. In some embodiments, the bonding interface 7 can comprise silicon nitride, silicon oxynitride, silicon oxycarbonitride, or silicon carbonitride, sapphire, oxides of aluminum, glass, ceramic material, even glass-ceramics or even polymeric material. As explained herein, the direct bond can comprise covalent bonds, which are stronger than van Der Waals bonds. The nonconductive bonding layers 5a, 5b can also comprise polished bonding surfaces 8a, 8b that are planarized to a high degree of smoothness.

In various embodiments, the metal-to-metal bonds between the contact pads 4a, 4b can be joined such that copper grains grow into each other across the bonding interface 7. In some embodiments, the copper can have grains oriented along the 111 crystal plane for improved copper diffusion across the bonding interface 7. The bonding interface 7 can extend substantially entirely to at least a portion of the bonded contact pads 4a, 4b, such that there is substantially no gap between the nonconductive bonding layers 5a, 5b at or near the bonded contact pads 4a, 4b. In some embodiments, a barrier layer (not shown in FIGS. 1A-1B) may be provided under the contact pads 4a, 4b (e.g., which may include copper). In other embodiments, however, there may be no barrier layer under the contact pads 4a, 4b, for example, as described in US 2019/0096741, which is incorporated by reference herein in its entirety and for all purposes.

Beneficially, the use of the hybrid bonding techniques described herein can enable extremely fine pitch p between adjacent contact pads 4a or 4b, and/or small pad sizes. For example, in various embodiments, the pitch p (see FIG. 1A) between adjacent pads 4a (or 4b) can be in a range of 0.5 microns to 25 microns, in a range of 0.75 microns to 25 microns, in a range of 1 micron to 25 microns, in a range of 1 micron to 10 microns, or in a range of 1 micron to 5 microns. Further a major lateral dimension (e.g., a pad diameter) can be small as, e.g., in a range of 0.25 microns to 8 microns, in a range of 0.25 microns to 5 microns, or in a range of 0.5 microns to 5 microns. Apart from pads 4a, 4b, conductive vias and traces of pitches similar to those of the pads may be disposed or embedded in the nonconductive bonding layers 5a, 5b at the bonding interface 7.

In various embodiments, the second element 3 can comprise a singulated device die, and the first element 2 can comprise a wafer or a panel. In other embodiments, both elements 2, 3 can comprise a singulated device die. In such an embodiment, the second element 3 may be initially provided in wafer form or larger substrate and singulated to form the singulated first element 3. However, the singulation process and/or other processing steps may produce debris that can contaminate the planar bonding surface 8a or 8b, which can leave voids and/or defects when two elements 2, 3 are bonded. Accordingly, prior to singulation, a protective layer can be provided over the bonding surface 8a or 8b before activation and direct bonding in order to prevent debris from contaminating the bonding surface 8a or 8b. The protective layer (not shown) can comprise an organic or inorganic layer (e.g., a photoresist) that is deposited (e.g., spin-coated onto) the bonding surface 8a or 8b. Additional details of the protective layer may be found throughout U.S. Pat. No. 10,714,449, the entire contents of which are incorporated by reference herein in their entirety and for all purposes.

The wafer containing the first element 2 can be singulated using any suitable method. The protective layer over the bonding surface 8a or 8b can beneficially protect the bonding surface 8a or 8b from debris. Before direct bonding, the protective layer can be removed from the bonding surface 8a or 8b with a cleaning agent, for example with a suitable solvent, such as an alkaline solution or other suitable cleaning agent as recommended by the supplier of the protective layer. The protective layer cleaning agent can be selected such that it does not substantially roughen the smooth bonding surface 8a or 8b of the nonconductive bonding layer 5a or 5b and does not substantially etch or contaminate the metal of the contact pad 4a or 4b to increase the recess of the pad metal after subsequent cleaning operations. An excessive pad recess may form a recess that is too deep, which may prevent (or reduce the strength of) pad-to-pad bonding at the appropriate annealing conditions (e.g., annealing temperature and times). The cleaning agent can be applied by a fan spray of the liquid cleaning agent or other known methods. For example, the cleaned bonding surface 8a, 8b can be ashed (e.g., using an oxygen plasma) and cleaned with deionized water (DIW). In some embodiments, the cleaned element 2, 3 can be activated before direct bonding. Other dies as needed may bonded over the back side 15 of cleaned and prepared element 3. The bonded structure 1 may be further singulated by known methods after the various needed further processing steps. The further processing steps may comprise thinning the back side 15 of bonded element 3 die or activation the back side 15 of bonded element 3 and directly bonding additional dies to the back side 15 or coating the back side 15 of the bonded element 3 with a dielectric layer for example.

As shown in FIGS. 2A-2B, in some high temperature and/or high current density applications and/or for smaller interconnects, electromigration within a conventional interconnect 26 can create voids 22. For example, voids 22 can be formed at an interface between conductive layers, which can reduce the reliability of the contacts and/or the bonded structure. FIGS. 2A and 2 B illustrate conventional interconnects 26 that contain such voids 22 at the interface between a lower conductive layer 62, which can include lateral traces (not shown), and an upper conductive layer 100, which can include a dual damascene contact pad and via. The lower conductive layer 62 and upper conductive layer 100 can be disposed in a nonconductive layer 56, which can comprise a dielectric material, such as an inorganic dielectric material, such as silicon dioxide. The constriction between the conductive layers 62, 100 at the via and the deposition interface contribute to electromigration causing voids 22. FIG. 2A shows electromigration failure in a conventional interconnect 26 that can comprise copper, and FIG. 2B shows a schematic of a modified conventional interconnect 26 that is formed through the process of direct hybrid bonding. In FIG. 2B, a conventional interconnect 26 is shown in which two elements 42, 44 are directly bonded at a bonding surface 106. A first element 42 has a lower conductive layer 62 disposed in a nonconductive layer 56. Provided on the lower conductive layer 62 is a conventional top barrier layer 28. The nonconductive top barrier layer 28 is further described below. A second element 44—bonded to the first element 42 at bonding interface 106—has a lower conductive layer 124 of the second element 44 and a contact structure 130 of the second element 44, the contact structure 130 of the second element 44 being analogous to the upper conductive layer 100 of the first element 42.

Such problems created by voids 22 are not limited to copper metallization. Accordingly, various embodiments here can reduce or suppress or eliminate electromigration failure within contact structures of semiconductor elements of bonded structures. Electromigration failure in bonded structures that are formed through the process of direct hybrid bonding can be mitigated or eliminated by, for example, forming redundant barriers and structures that can, e.g., provide an alternative (redundant) current pathway. As mentioned above, such redundant barriers and structures become more important in higher temperature applications, higher current density applications, and as metallic interconnect dimensions get smaller.

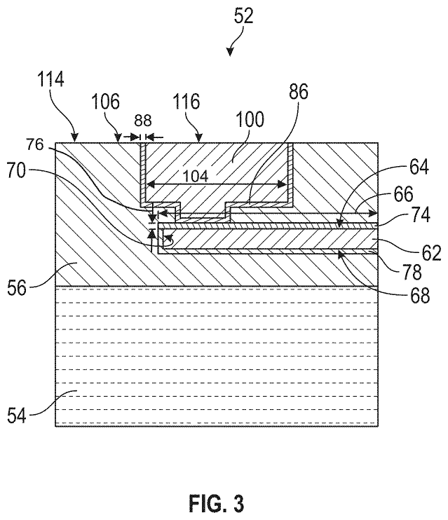

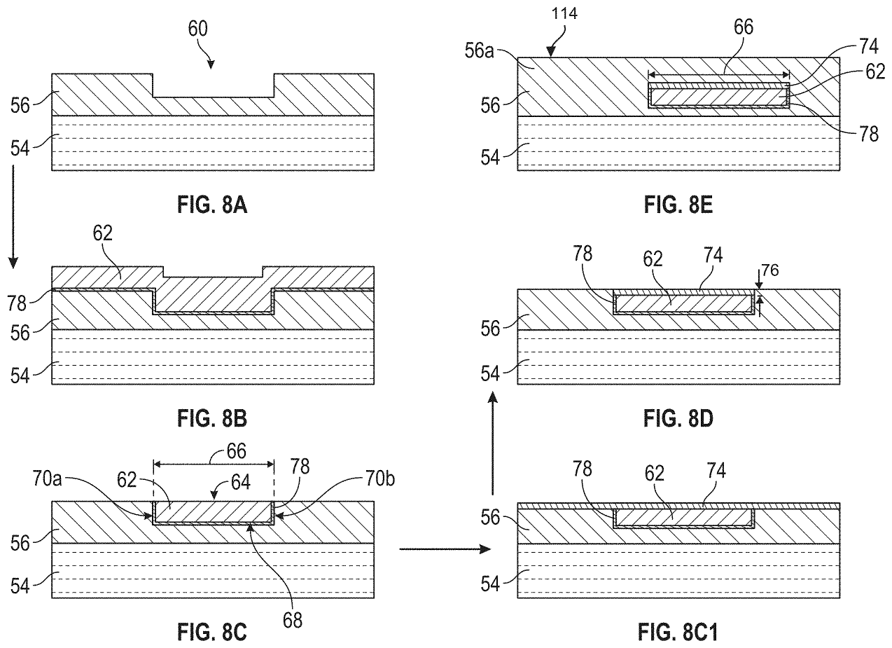

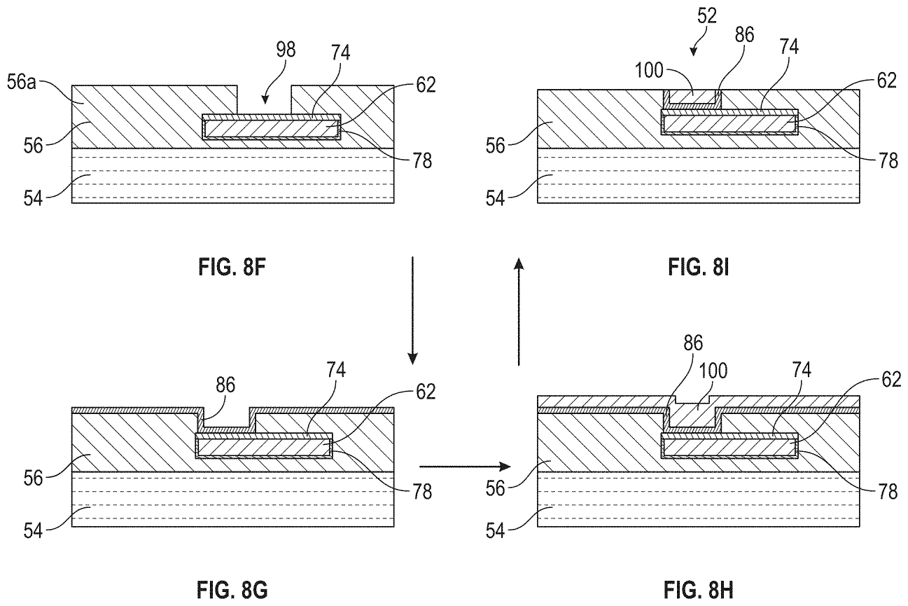

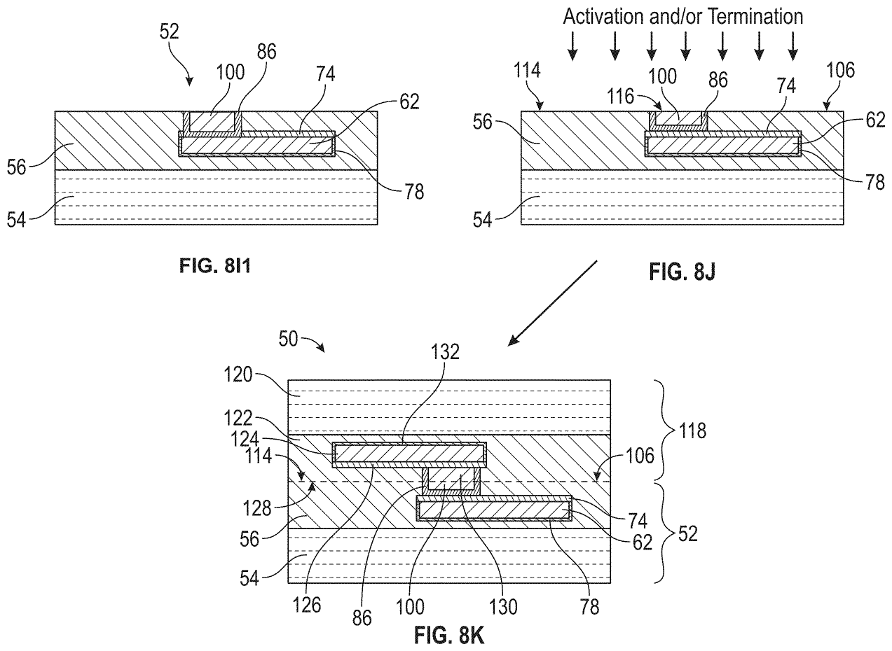

FIG. 3 is a schematic side sectional view of a semiconductor element 52, according to various embodiments. The semiconductor element 52 can include a semiconductor portion 54. The semiconductor portion 54 can comprise a semiconductor material, such as silicon or any other suitable semiconductor material. The semiconductor portion 54 may include one or multiple devices, e.g., active devices (such as transistors), passive devices (such as resistors), etc. A nonconductive layer 56 (e.g., a nonconductive bonding layer) can be provided on the semiconductor portion 54 and can have an upper nonconductive surface 114 forming a first portion of a bonding surface 106 of the semiconductor element 52. The nonconductive layer 56 can comprise a dielectric material in some embodiments. For example, the nonconductive layer 56 can comprise an inorganic dielectric material, such as silicon oxide, silicon nitride, silicon carbide, silicon oxycarbonitride, etc., and may include a higher concentration of nitrogen and/or fluorine at the upper nonconductive surface 114 as discussed above. In some embodiments, the nonconductive layer 56 comprises a plurality of dielectric layers disposed on the semiconductor portion 54. In other embodiments, the nonconductive layer 56 comprises a single dielectric layer. The upper nonconductive surface 114 can be prepared for direct bonding to a second semiconductor element 118 (shown in FIG. 8K) as explained above.

The metallization structure of FIG. 3 includes an upper contact structure (e.g., an upper conductive layer 100) and a lower conductive feature (e.g., a lower conductive layer 62) that are electrically connected. The lower conductive layer 62 can have an upper surface 64 (which has a length 66), a lower surface 68, and side surface(s) 70. The lower surface 68 and side surface(s) 70 of the lower conductive layer 62 can be lined with a lower barrier layer 78, which is described below. The upper conductive layer 100 of the illustrated semiconductor element 52 embodiment can include a contact structure that can be at least partially embedded in the nonconductive layer 56 and can have an upper contact surface 116 forming a second portion of the bonding surface 106 of the semiconductor element 52. In some embodiments, as explained above, the upper contact surface 116 can be recessed below the upper nonconductive surface 114 prior to direct bonding. The contact structure can be formed of a first material. As shown, the contact structure can comprise an upper conductive layer 100 that comprises copper. In the illustrated embodiment, the upper conductive layer 100 comprises a dual damascene structure including a structure in which the portion of the upper conductive layer 100 that is closer to the upper contact surface 116 is laterally wider than the portion of the upper conductive layer 100 that is closer to the lower conductive layer 62. In other embodiments, the upper conductive layer 100 can comprise a single damascene structure.

Also as shown in FIG. 3, the semiconductor element 52 can include the lower conductive feature (e.g., the lower conductive layer 62) below and electrically connected to the contact structure (e.g., the upper conductive layer 100). The lower conductive layer 62 can comprise copper in various embodiments. In the illustrated embodiment, the lower conductive layer 62 comprises lateral traces that can serve as a redistribution layer (RDL) or a back end of the line (BEOL) layer embedded in the nonconductive layer 56. The RDL can communicate laterally with other circuits and/or vias.

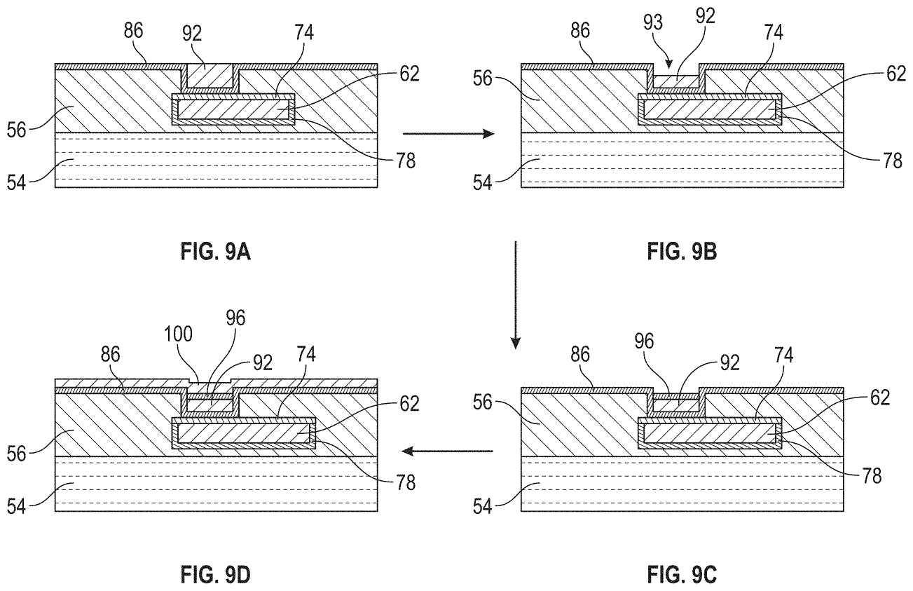

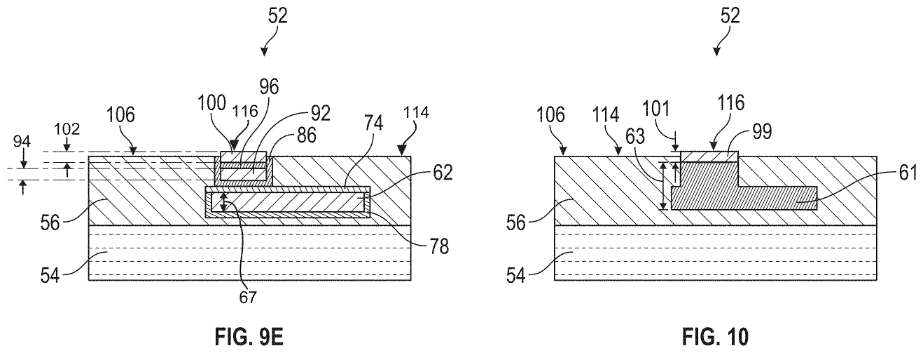

The semiconductor element 52 of FIG. 3 can include a barrier layer 74 (alternatively referred to as a “first barrier layer”) disposed between the upper conductive layer 100 and the lower conductive layer 62. The barrier layer 74 can be formed of a second material different from the first material of the upper conductive layer 100 and also different from the materials of the second and third barrier layers 86, 96 described below (the third barrier layer 96 is shown in FIG. 9D). The second material of the first barrier layer 74 can have an electrical resistivity lower than that of conventional barrier materials such as Ta, TaN, WN, etc. (see below discussion of the materials of the second and third barrier layers 86, 96). In particular, the electrical resistivity of the second material of the first barrier layer 74 can be less than 80×10⁻⁸ mΩ (for example, less than 60×10⁻⁸ mΩ) at 20° C. and a melting point greater than 1200° C. In some embodiments, the electrical resistivity of the second material can be in a range of 4.5×10⁻⁸ mΩ at 20° C. to 60×10⁻⁸ mΩ at 20° C., or in a range of 4.5×10⁻⁸ mΩ at 20° C. to 30×10⁻⁸ mΩ at 20° C. In some embodiments, the melting point of the second material can be in a range of 1200° C. to 3600° C.

In various embodiments, the second material of the first barrier layer 74 can comprise at least one of copper, alpha-tantalum, hexagonal-tantalum nitride, cobalt, tungsten, vanadium, molybdenum, and nickel. In some embodiments, the second material comprises an alloy. For example, the alloy can comprise at least one of cobalt tungsten phosphate (CWP), cobalt phosphate (CoP), low phosphorus nickel phosphate (NiP) with phosphorus less than 3.5%, low phosphorus and a low tungsten (NiWP) with phosphorus and tungsten less than 3.5%, nickel tungsten (NiW), titanium tungsten (TiW), and nickel vanadium (NiV), and stoichiometric and non-stoichiometric borides. The stoichiometric borides may comprise nickel borides (NiB, Ni₂B, Ni₃B) and cobalt borides. In some embodiments, the second material comprises an alloy and metallic element stack, for example TaN/Ta, TiN/Ti, TiW/Ti, TiW/Mo or TiW/Co. In such cases, the alloy can serve as a seed layer for the coating of the metallic element. The thickness of the alloy seed may vary between 2 to 20 nm and the thickness of the metallic element may range from 25 to 1000 nm. In some applications, the alloy seed can serve to reduce the resistivity of the coated metallic element, for example, the resistivity of thin film Mo is about 13 to 18×10⁻⁸ mΩ at 20° C. A very thin 3 nm coating of TiW seed layer can reduce the resistivity of a Mo overcoat by more than 40%. Additional information about the second material is shown in Table 1 below.

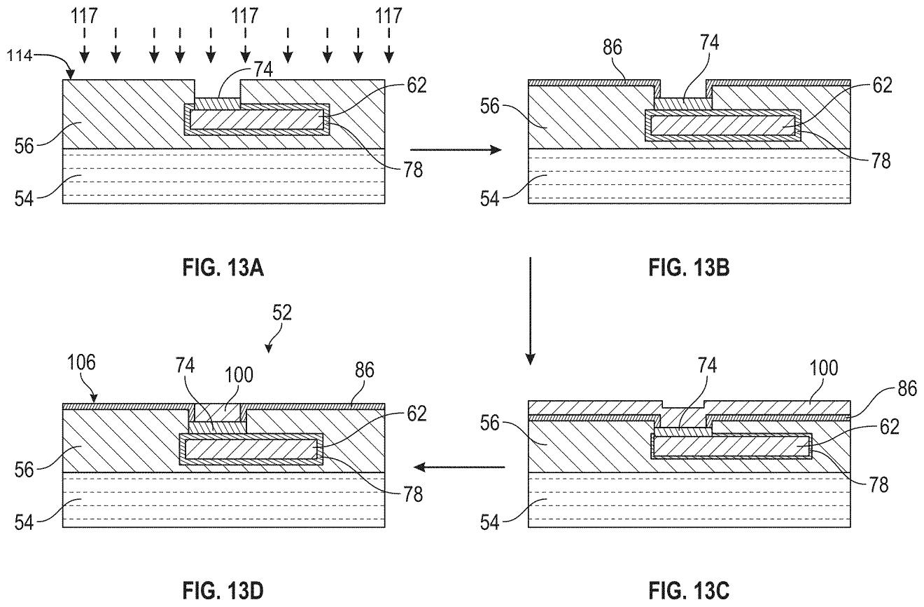

As shown in FIG. 3, a second barrier layer 86 can be provided to line at least a portion of a cavity 98 (shown in FIG. 8F) in which the upper conductive layer 100 is disposed, with the second barrier layer 86 disposed between the nonconductive layer 56 and the upper conductive layer 100. Such a second barrier layer 86 lines sidewalls of the cavity 98 (shown in FIG. 8F) and can serve to inhibit diffusion of the bulk of the upper conductive layer 100 (e.g., copper) into the nonconductive layer 56 (e.g., silicon oxide-based material). This inhibition of diffusion can be beneficial because such diffusion can risk short circuiting with other conductive features. The illustrated second barrier layer 86 also extends along the bottom of the upper conductive layer 100 (i.e., the bottom of the lower via portion of the upper conductive layer 100 nearest to the lower conductive layer 62), although the skilled artisan will appreciate that bottomless barrier liners are also known in the art and illustrated, for example, in FIG. 13D. In the illustrated embodiment, the second barrier layer 86 comprises a third material different from the first material of the upper conductive layer 100 and the second material of the first barrier layer 74. For example, in the illustrated embodiment, the third material comprises a metal nitride, such as tantalum nitride. In the illustrated embodiment, a thickness 76 of the first barrier layer 74 can be greater than a thickness 88 of the second barrier layer 86.

In FIG. 3, the first barrier layer 74 can be disposed along a length 66 of an upper surface 64 of the lower conductive layer 62, the length 66 being greater than a width 104 of the upper conductive layer 100. The lower conductive layer 62 can be encapsulated by the first barrier layer 74 along its upper surface 64 and by one or more additional barrier layers along a lower surface 68 and side surface(s) 70 of the lower conductive layer 62. In the illustrated embodiment, the one or more additional barrier layers comprise a lower barrier layer 78 that lines a cavity in which the lower conductive layer 62 is disposed. The lower barrier layer 78 can include a material different from the first and second materials, but can be different from or the same as the third material. For example, in the illustrated embodiment, the lower barrier layer 78 can comprise the same material as the second barrier layer 86, e.g., a metal nitride such as tantalum nitride or titanium nitride. In other embodiments, as explained herein, the one or more additional barrier layers along the lower 68 and side surfaces 70 of the lower conductive layer 62 can comprise the same material as the second material of the first barrier layer 74.

FIGS. 4A and 4B illustrate conventional interconnects 26 in which copper is disposed in cavities in a nonconductive layer 56, in which the cavities are lined with a conventional barrier layer 24, e.g., a metal nitride such as tantalum nitride. The copper can form each of a lower conductive layer 62 and an upper conductive layer 100, and the upper conductive layer 100 can be at least partially lined with a conventional barrier layer 24, which can comprise the same material as the conventional barrier layer 24 adjacent the lower conductive layer 62, e.g., a metal nitride such as tantalum nitride. FIG. 4A shows a schematic of such a conventional interconnect 26, and FIG. 4B shows a schematic of the direction of electron flow 20 within such a conventional interconnect 26 that contains voids 22. As shown in FIGS. 4A-4B, electromigration (e.g., current crowding) can occur when current travels from a higher conductivity material (such as copper, which may be a constituent material of the lower conductive layer 62 and/or the upper conductive layer 100) to a lower conductivity material (such as a conventional barrier layer 24 ), and/or when travelling from a wider, more conductive path to a narrower, more resistive path. The induced electromigration stress may create voids 22 which can reduce the electrical reliability or performance of the interconnect. In some embodiments, the upper surface of the lower conductive layer 62 may be coated with an interlayer dielectric material (not shown) such as SiN prior to coating of the nonconductive layer 56. The interlayer dielectric coating enhances the adhesion of nonconductive layer 56 to upper surface of the lower conductive layer 62.

By contrast, as shown in FIG. 4C-4D, in a semiconductor element 52 according to various embodiments, the second material of the first barrier layer 74 can beneficially be selected to have a low electrical resistivity and a high melting point, which can reduce electromigration and the likelihood of voids 22. FIGS. 4C and 4D show a semiconductor element 52 comprising a nonconductive layer 56, with a lower conductive layer 62 and an upper conductive layer 100 at least partially embedded in the nonconductive layer 56. A conventional barrier layer 24 can be disposed between the upper conductive layer 100 and the nonconductive layer 56 within which it is at least partially embedded. And another conventional barrier layer 24 can line either or each of the lower surface 68 or the side surface(s) 70 of the lower conductive layer 62.

In further reference to FIGS. 4C and 4D, even if electromigration stress is introduced, the first barrier layer 74 can act as redundant electrical pathways between the upper conductive layer 100 and the lower conductive layer 62 to avoid open circuits and thereby improve electrical connections and electrical reliability. As shown in FIG. 4D, even if voids 22 were to form within the lower conductive layer 62 near the upper conductive layer 100, the direction of electron flow 20 would not be impeded, because the electrons would still be able to flow along the conductive first barrier layer 74.

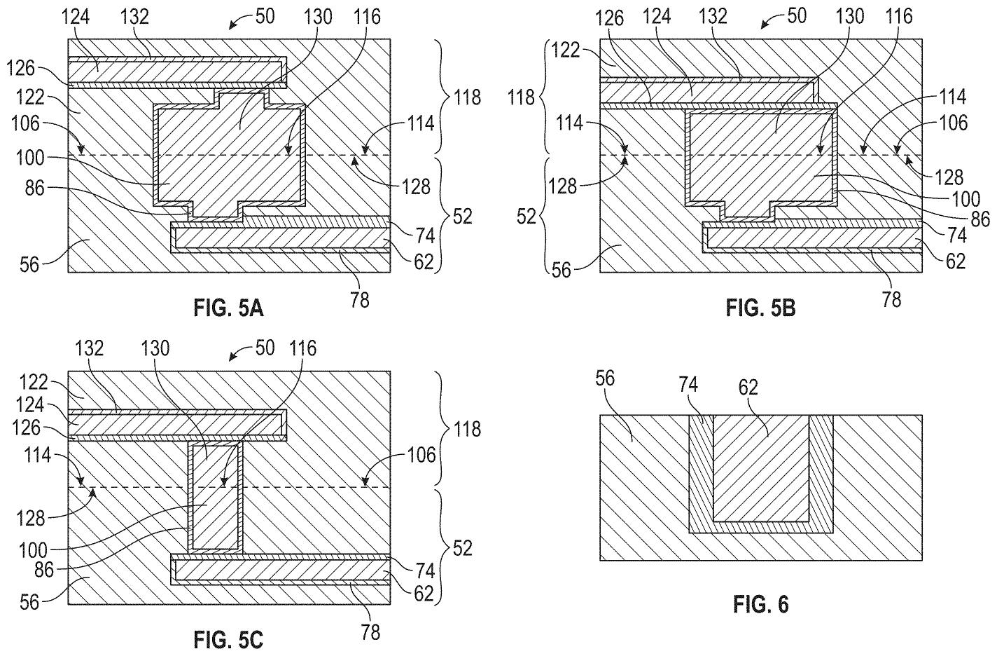

FIGS. 5A-5C provide examples of directly bonded structures 50 with redundant current pathways in the form of metallic first barrier layers 74, 126. FIGS. 5A-5C illustrate bonded structures 50 in which a first semiconductor element 52 can be bonded to a second semiconductor element 118 along a bonding surface 106. Specifically, FIGS. 5A-5C illustrate bonded structures 50 in which the nonconductive layer 56 of the first semiconductor element 52 is directly bonded to a second nonconductive layer 122 of the opposing second semiconductor element 118, and in which the upper conductive layer 100 of the first semiconductor element 52 is directly bonded to the contact structure 130 of the second semiconductor element 118. The nonconductive layers 56, 122 can be directly bonded by bonding the upper nonconductive surface 114 of the first semiconductor element 52 to a second upper nonconductive surface 128 of the second semiconductor element 118. And the upper conductive layer 100 of the first semiconductor element 52 can be bonded to the contact structure 130 of the second semiconductor element 118 by bonding the upper contact surface 116 of the first semiconductor element 52 to its corresponding surface of the second semiconductor element 118.

In FIGS. 5A-5C, the first and second semiconductor elements 52, 118 are shown as directly bonded along a bonding surface 106. The first and second semiconductor elements 52, 118 can have similar components. The first semiconductor element can include a lower conductive layer 62 encapsulated by a lower barrier layer 78 and a first barrier layer 74, as well as an upper conductive layer 100 at least partially lined by a second barrier layer 86; and the second semiconductor element can include a second lower conductive layer 124 encapsulated by a lower barrier layer 132 and a first barrier layer 126 of the second semiconductor element 118, as well as a contact structure 130 of the second semiconductor element 118 at least partially lined by a second barrier layer that can be similar to the second barrier layer 86 of the first semiconductor element 52. As shown, the upper conductive layer 100 of the first semiconductor element 52 can comprise a contact structure, such as single and/or dual damascene structures, and the first barrier layer 74 (comprising the second material) can provide redundant current pathways. In each of FIGS. 5A-5C, the first barrier layer 74 of the first semiconductor element 52 provides a bottom redundant current pathway, and the first barrier layer 126 of the second semiconductor element 118 provides a top redundant current pathway. The first barrier layer 126 of the second semiconductor element 118 can comprise a second material as described herein.

FIG. 5A illustrates a schematic of two direct bonded semiconductor elements 52, 118, containing dual damascene features. FIG. 5B illustrates a schematic of two direct bonded semiconductor elements 52, 118, containing single and dual damascene features. And FIG. 5C illustrates a schematic of two direct bonded semiconductor elements 52, 118 containing single features.

TABLE 1
Example Materials (shown in *) that can be used as part of the second material

| Material Properties | Cu | Co* | W* | V* | Ni* | Ta | Ti. |
|---|---|---|---|---|---|---|---|
| Resistivity (ρ 10⁻⁸ | 1.8-2.0 | 6.2 | 5.6 | 19.7 | 7 | 200-350 | 40 |
| mΩ at 20° C.) | | | | | | | |
| Thermal expansion | 17 | 13 | 4.5 | 8.3 | 13.4 | 6.3 | 8.6 |
| (×10⁻⁶ K⁻¹) | | | | | | | |
| Young's Modulus | 130 | 209 | 340 | 125 | 200 | 186 | 116 |
| (GPa) | | | | | | | |
| Melting Point (° C.) | 1084.6 | 1495 | 3410 | 1735 | 1455 | 3017 | 1668 |

Table 1 illustrates examples of second materials that can, for example, be used for the first barrier layers 74, 126. Such materials are noted in Table 1 with an asterisk (*). In Table 1, it is generally desirably to have a material with a low resistivity (so as to reduce electrical losses), a low coefficient of thermal expansion, and a high melting point. Example materials include Co, W, V, Ni, or alloys such as CWP, CoP, NiP, NiW or NiV, or laminates for example TiW/Co, TiW/Mo, TaN/Ta, TaN/Ti, TiN/Ta, etc. The use of laminates can, for example, reduce electrical resistivity by, e.g., reducing defect density. The example criteria for electromigration resistance shown in Table 1 are high melting points and low resistivity (i.e., high conductivity). Desirably, conductivity is further improved by increasing thickness 76 of the first barrier layer 74 as compared to conventional second barrier layers 86. For example, the thickness 76 of the first barrier layer 74 can be selected to be between about 1.5 times and about 4 times the thickness 88 of the second barrier layer 86, more particularly between about 2 times and about 3 times the thickness 88 of the second barrier layer 86 (e.g., 100-150 nm vs. 5-50 nm). In some embodiments, the thickness 76 of the first barrier layer 74 can be in a range of 10-150 nm, or in a range of 100-150 nm. The thickness 76 of the second material (100-150 nm) can be at least 2-3 times greater than the thickness 88 of a sidewall barrier (Ta or Ti (5-50 nm)) of a second barrier layer 86.

In FIG. 6, the conductive layer 62 can comprise a metal such as copper that has a low resistivity (e.g., less than 10×10⁻⁸ mΩ), and the first barrier layer 74 can comprise one or more second materials as noted above, which also has a low resistivity (e.g., less than 100×10⁻⁸ mΩ) and also a high melting point (e.g., greater than 1200° C.). The use of the first barrier layer 74 in FIG. 6 can provide electrical redundancy for the bonded structures 50 in FIGS. 5A-5C, and can help prevent or mitigate the effects of electromigration of the metal atoms from within the conductive layer 62 into the surrounding nonconductive layer 56 into which the conductive layer 62 can be at least partially embedded. It should also be appreciated that FIG. 6 shows that the first barrier layer 74 is not limited to a being a horizontal layer, and that in some embodiments, the first barrier layer 74 can also be a vertical layer.

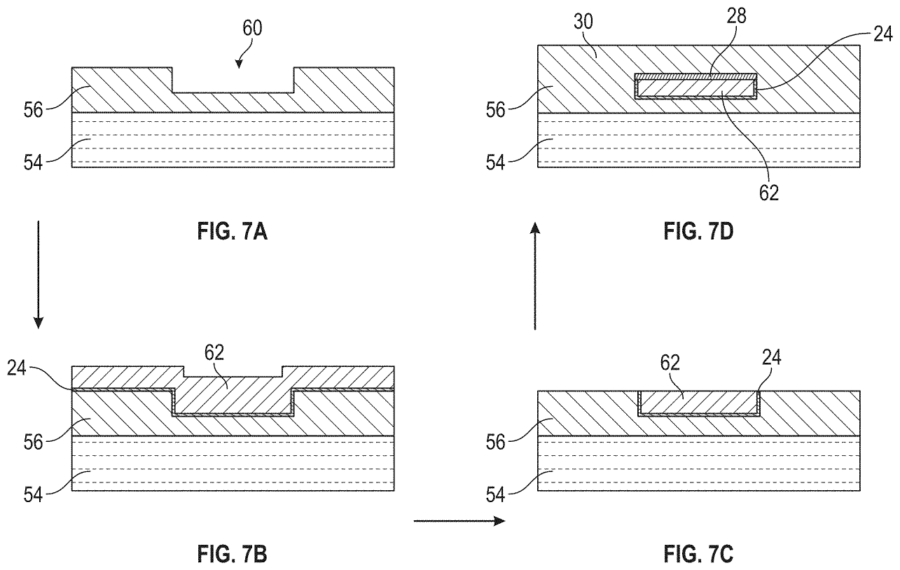

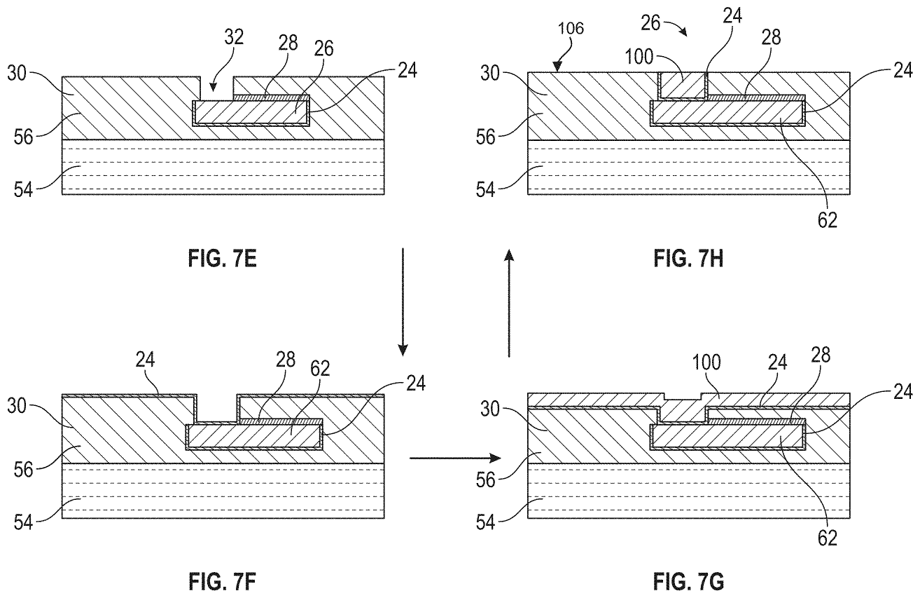

FIGS. 7A-7H illustrate a process flow for forming a conventional interconnect 26 with a conventional bonding layer and contact structure. In FIG. 7A, a nonconductive layer 56 can be provided on a semiconductor portion 54, and an RDL or BEOL trace cavity 60 can be formed in the nonconductive layer 56. In FIG. 7B, a conventional barrier layer 24 (e.g., a metal nitride such as TaN) and a lower conductive layer 62 (e.g., copper) can be provided in the cavity 60. In FIG. 7C, excess metal of the lower conductive layer 62 can be removed and the nonconductive layer 56 can be planarized by CMP methods. In FIG. 7D, a conventional nonconductive top barrier layer 28 (e.g., SiN, which can be, for example, 30 to 100 nm thick) can be provided over the lower conductive layer 62. Although not shown, the conventional nonconductive top barrier layer 28 can be blanket deposited across the full surface of the nonconductive layer 56, and thereby extend beyond the length of the lower conductive layer 62. FIG. 7D also shows that a thicker dielectric layer 30 can be coated over the conventional nonconductive top barrier layer 28. The thicker dielectric layer 30 can also be coated over the nonconductive layer 56. Throughout this application, where applicable, the thicker dielectric layer 30 and the nonconductive layer 56 can be discussed either as separate components or as being a consolidated nonconductive layer 56. Expressed differently, where applicable, “nonconductive layer 56” can refer either to just the portion of the nonconductive layer 56 at the same level as and below the lower conductive layer 62 (as shown in FIG. 7C), or to the larger nonconductive layer 56 resulting from coating the thicker dielectric layer 30 in FIG. 7D. Expressed yet differently, it will be appreciated that the nonconductive layer 56 has been described herein as comprising a single dielectric layer in certain embodiments, while comprising a plurality of dielectric layers in other embodiments. In some embodiments, the thicker dielectric layer 30 may be planarized. In FIG. 7E, an opening 32 can be formed in the thicker dielectric layer 30 and in the conventional nonconductive top barrier layer 28, to expose the lower conductive layer 62 such as an RDL or BEOL layer. In FIG. 7F, another conventional barrier layer 24 can be provided in the opening 32 over the lower conductive layer 62. In FIG. 7G, an upper conductive layer 100 (e.g., copper) can be provided over the conventional barrier layer 24. The upper conductive layer 100 can electrically contact the lower conductive layer 62 and fill the opening 32 in the thicker dielectric layer 30. In FIG. 7H, the upper conductive layer 100 and the thicker dielectric layer 30 can be planarized to form the conventional interconnect 26 and bonding layer with a smooth planner bonding surface 106. The bonding surface 106 of FIG. 7H may be cleaned, prepared, activated and bonded to form a structure similar to that of FIG. 4A without the electromigration defect.

FIGS. 8A-8K illustrate a process flow for forming a semiconductor element 52 with its constituent conductive layers 62, 100 and barrier layers 74, 78, 86; and how to then form a bonded structure 50 comprising two semiconductor elements 52, 118, according to various embodiments. In FIG. 8A, a nonconductive layer 56 can be provided on a semiconductor portion 54, and an RDL or BEOL trace cavity 60 can be formed in the nonconductive layer 56. This step can be completed in a manner similar to the step shown in FIG. 7A. In FIG. 8B, a lower barrier layer 78 and a lower conductive layer 62 (e.g., copper) can be provided in the cavity 60. In the illustrated embodiment, the lower barrier layer 78 can comprise a conventional barrier layer 24 material, e.g., a metal nitride such as TaN or TiN. In other embodiments, as explained herein, the lower barrier layer 78 can comprise the second material of the first barrier layer 74. In FIG. 8C, excess metal and the nonconductive layer 56 can be planarized, initially stopping on the lower barrier layer 78 and then removing the lower barrier layer 78 from over the nonconductive layer 56. In some embodiments as illustrated in FIG. 8C, a determined portion of the top surface of the lower conductive layer 62 may be selectively remove, for example by wet etching methods. The thickness of the determined portion, for example may range between 20 nm to 300 nm. The lower conductive layer 62 can have an upper surface 64 (which has a length 66), a lower surface 68, and side surface(s) 70a, 70b. The lower surface 68 and side surface(s) 70a, 70b of the lower conductive layer 62 can be lined with a lower barrier layer 78. In FIG. 8C1, the first barrier layer 74 comprising a second material can be provided over the nonconductive layer 56 and over the remaining lower conductive layer 62. The first barrier layer 74 can be selectively removed from over the nonconductive layer 56 by chemical mechanical polishing (CMP) method to form the structure of FIG. 8D. In other embodiments, as in FIG. 8D, the first barrier layer 74 comprising the second material can be selectively provided over the lower conductive layer 62. The first barrier layer 74 can have a thickness 76 greater than that of the lower barrier layer 78 or that of the second barrier layer 86. A variety of techniques can be employed to pattern the first barrier layer 74 to overlie the lower conductive layer 62, such as damascene processing (recessing the lower conductive layer 62, depositing the second material, and polishing); blanket deposition, masking and etching; and selective deposition. In FIG. 8E, another nonconductive layer 56a (alternatively referred to with the numeral 56, as a single item together with the nonconductive layer provided on the semiconductor portion 54) can be provided over the lower conductive layer 62. In FIG. 8E, the lower conductive layer 62 can be encapsulated by the combination of the lower barrier layer 78 lining its lower and side surfaces 68, 70a, 70b (shown in FIG. 8C), and the first barrier layer 74 lining the length 66 of its upper surface 64 (shown in FIG. 8C). In some embodiments, a thin interlayer nonconductive layer (not shown), for example SiN may be coated over the substrate prior to the coating of the nonconductive layer 56a. The thin interlayer nonconductive layer can help couple the nonconductive layer 56a to the lower conductive layer 62.

In some embodiments, the nonconductive layer 56 can be planarized. The upper nonconductive surface 114 of the nonconductive layer 56, which will form a portion of the bonding surface 106 (shown in FIG. 8K), can be an inorganic semiconductor or dielectric material as noted above. In FIG. 8F, a cavity 98 can be formed in the nonconductive layer 56, 56a to extend to the first barrier layer 74. In FIG. 8G, a second barrier layer 86 can be provided in the cavity 98 over the first barrier layer 74. In the illustrated embodiment, the second barrier layer 86 can comprise any of the second materials described herein, e.g., a cobalt alloy, a nickel alloy, etc. The first and second barrier layers 74, 86 can comprise the same material in some embodiments (e.g., a cobalt alloy, a nickel alloy, etc.). In other embodiments, the first and second barrier layers 74, 86 can comprise different materials (e.g., the first barrier layer 74 can comprise a cobalt alloy and the second barrier layer 86 can comprise a nickel alloy, or vice versa). In still other embodiments, such as the structures shown in FIGS. 4C and 4D, the first barrier layer 74 can comprise any of the second materials (e.g., cobalt alloy, nickel alloy, etc.), and the second barrier layer 86 can comprise a conventional barrier layer 24 material, such as a third material, for example a metal nitride such as tantalum nitride or titanium nitride. In FIG. 8H, an upper conductive layer 100 (e.g., copper) can be provided over the second barrier layer 86. In FIG. 8I, the upper conductive layer 100 and the nonconductive layer 56 can be planarized to form the semiconductor element 52. FIG. 8I1 shows an alternative embodiment. As shown in FIG. 8I, the second barrier layer 86 can contact the top of the first barrier layer 74, but as shown in FIG. 8I1, the second barrier layer 86 can extend into the first barrier layer 74 or all the way through the first barrier layer 74 into the lower conductive layer 62. The skilled artisan will notice that in any of these alternatives, the first barrier layer 74 still acts as a redundant path along which current can flow. In FIG. 8I1, the first barrier layer 74 may be disposed around the second barrier layer 86 and/or portions of the upper conductive layer 100.

Turning to FIG. 8J, the bonding surface 106 of the semiconductor element 52 can be formed. For example, the bonding surface 106 can be activated and/or terminated as discussed above. The bonding surface 106 of the semiconductor element 52 can comprise at least a nonconductive portion (e.g., an upper nonconductive surface 114) and a conductive portion (e.g., an upper contact surface 116). The upper nonconductive surface 114 can be an activated surface of the nonconductive layer 56, and the upper contact surface 116 can be the exposed surface of the upper conductive layer 100.

In FIG. 8K, a bonded structure 50 can be formed by directly bonding the semiconductor element 52 to a second semiconductor element 118 without an intervening adhesive. As shown in FIG. 8K, in some embodiments, the lower conductive layers 62, 124 of each semiconductor element 52, 118 can be encapsulated (e.g., completely enclosed by) one or more barrier layers (e.g., including first barrier layers 74, 126 and the lower barrier layers 78, 132). As explained herein, the lower barrier layers 78, 132 can comprise a conventional barrier layer 24 material such as Ta or TaN. In other embodiments, the lower barrier layers 78, 132 can comprise the same material as the first barrier layers 74, 126, e.g., one of the second materials described herein. Each semiconductor element 52, 118 also has a semiconductor portion 54, 120, which can comprise a semiconductor material, such as silicon. The first and second semiconductor elements 52, 118 are bonded at a bonding surface 106. The upper nonconductive surface 114 of the first semiconductor element 52 can be directly bonded to the second upper nonconductive surface 128 of the second semiconductor element 118, as described herein. The upper nonconductive surface 114 can be the activated surface of the nonconductive layer 56 of the first semiconductor element 52, and the second upper nonconductive surface 128 can be the activated surface of the second nonconductive layer 122 of the second semiconductor element 118. Additionally, the conductive portions of the semiconductor elements 52, 118—the upper conductive layer 100 of the first semiconductor element 52 and the contact structure 130 of the second semiconductor element 118—can be directly bonded. The contact structures (e.g., the upper conductive layer 100 of the first semiconductor element 52 and the contact structure 130 of the second semiconductor element 118) can be at least partially lined by a barrier layer (e.g., the second barrier layer 86).

FIGS. 9A-9E illustrate a process flow for forming a semiconductor element 52 with its constituent conductive layers 62, 92, 100 and barrier layers 74, 78, 86, 96, according vto various embodiments. The embodiment of a semiconductor element 52 shown in FIG. 9E is similar to the one shown in FIG. 8I, but the semiconductor element 52 shown in FIG. 9E has an additional conductive layer (e.g., an intermediate conductive layer 92) between the lower and upper conductive layers 62, 100 and an additional barrier layer (e.g., a third barrier layer 96).

As shown in FIG. 9A, the semiconductor element 52 can comprise a nonconductive layer 56 on a semiconductor portion 54. Embedded in the nonconductive layer 56 can be a lower conductive layer 62 that can be encapsulated by at least one barrier layer (e.g., a first barrier layer 74 and a lower barrier layer 78). Disposed on the first barrier layer 74 can be a second barrier layer 86, which is similar to the step shown in FIG. 8G. In FIG. 9A, an intermediate conductive layer 92 (e.g., cobalt or nickel or tungsten) is disposed above the first barrier layer 74. In the illustrated embodiment, the lower barrier layer 78, the first barrier layer 74, and the second barrier layer 86 can comprise any of the second materials disclosed herein. The material formulations for the lower barrier layer 78, the first barrier layer 78, and the second barrier layer 86 may be the same, generally similar, or may differ.

Turning to FIG. 9B, an opening or controlled recess 93 can be formed in the intermediate conductive layer 92 by selectively removing a controlled portion of the intermediate conductive layer 92. The controlled recess 93 can be formed by, for example, wet methods and can be recessed to a depth of, for example, between 50 and 500 nm. In FIG. 9C, a third barrier layer 96 comprising a top encapsulation layer can be formed over the remaining intermediate conductive layer 92. The third barrier layer 96 can comprise any of the second materials described herein. The third barrier layer 96 may be formed of a second material that is the same as or different from the second material(s) used for the lower barrier layer 78, the first barrier layer 74, and/or the second barrier layer 86. Turning to FIG. 9D, an upper conductive layer 100 (e.g., copper, copper-zinc alloy, copper-cadmium alloy, copper-tin alloy, copper-cobalt alloy, <111> copper) can be provided over the second barrier layer 86 and over the third barrier layer 96 by, for example, physical vapor deposition, electroless or electrolytic plating.

FIG. 9E illustrates a semiconductor element 52 with its constituent conductive layers 62, 92, 100 and barrier layers 74, 78, 86, 96. In FIG. 9E, a planarization process can be performed to remove excess conductive material from the upper conductive layer 100, and can also remove the unwanted second barrier layer 86 that overlies the nonconductive layer 56. The remaining upper conductive layer 100 over the intermediate conductive layer 92 can serve as a contact structure forming a portion of the bonding surface 106 over the third barrier layer 96. The contact structure (e.g., the upper conductive layer 100) can comprise copper, copper alloys or other conductive material that can be readily planarized or polished and that can be employed in direct hybrid bonding. Beneficially, the contact structure (e.g., the upper conductive layer 100) in FIG. 9E can serve as the bonding surface 106 to connect to a contact structure 130 of a second semiconductor element 118 (shown in FIGS. 5A-C). The upper conductive layer 100 may serve as a bonding material. Moreover, a thickness 102 of the upper conductive layer 100 can be less than one or both of a thickness 94 of the intermediate conductive layer 92 and a thickness 67 of the lower conductive layers 62. The multiple barrier layers 74, 78, 86, 96 can each comprise one of the second materials described herein, such as cobalt alloys, and thus provide multiple redundant pathways to reduce and provide alternative pathways around any voids 22 (shown in FIGS. 2A-B) formed, such as from electromigration, while the contact structure (e.g., the upper conductive layer 100) at the bonding surface 106 provides superior direct bonding properties. The skilled artisan will appreciate that the contact structure (e.g., the upper conductive layer 100) may be recessed such that the upper contact surface 116 is below the upper nonconductive surface 114 of the nonconductive layer 56. This can allow the contact structure to expand into metal-metal contact with another contact structure on a different element after the nonconductive materials initially bond, for example forming covalent bonds at room temperature and without application of pressure as disclosed herein. In other words, the contact structure (e.g., the upper conductive layer 100) can be recessed below the upper nonconductive surface 114 as a way to prepare the bonding surface 106 for the hybrid direct bonding process detailed above.

The embodiment shown in FIG. 9E provides advantages over conventional structures (such as those shown in FIG. 4A). The second material (for example, a Co-alloy) acts as a redundant conduction pathway should the material in the conductive layers (e.g., copper) become defective. Additionally, when the copper is encapsulated in a second material (for example, a Co-alloy), it is more resistant to stress-migration and electro-migration. And moreover, the second material (for example, a Co-alloy) of the barrier layer can diffuse into the copper of the conductive layers 62, 92, 100, which further enhances the reliability of the interconnection of the semiconductor element 52.

FIG. 10 illustrates another embodiment of a semiconductor element 52, according to various embodiments. Like other embodiments, the semiconductor element 52 illustrated in FIG. 10 can include a semiconductor portion 54 and a nonconductive layer 56 disposed on the semiconductor portion 54. The semiconductor element 52 can include a bonding surface 106 comprising an upper nonconductive surface 114 of the nonconductive layer 56 and an upper contact surface 116 of a contact structure 99. The contact structure 99 (like the upper conductive layer 100 shown in FIG. 9E) can comprise a first material described herein, such as copper. In FIG. 10, the semiconductor element 52 can comprise an electrically conductive barrier material 61 below and electrically connected to the contact structure 99. The contact structure 99 can extend across the full upper length of the electrically conductive barrier material 61. The electrically conductive barrier material 61 can comprise any of the second materials described herein including alloys (e.g., CWP, CoP, NiP, NiW, or NiV, etc.) and laminates (e.g., TiW/Co, TiW/Mo, TaN/Ta, TaN/Ti, TiN/Ta, etc.), and unlike prior embodiments the bulk of the conductive features (including, e.g., the lower conductive layer 62, the optional intermediate conductive feature 92, and the upper conductive layer 100, all of which are shown in FIG. 9E) is formed by the second material with the exception of the contact structure 99. For example, the electrically conductive barrier material 61 can have an electrical resistivity less than 50×10⁻⁸ mΩ at 20° C. and a melting point greater than 1200° C. In some embodiments, the electrical resistivity of the electrically conductive barrier material 61 can be in a range of 4.5×10⁻⁸ mΩ at 20° C. to 50×10⁻⁸ mΩ at 20° C. In some embodiments, the melting point of the electrically conductive barrier material 61 can be greater than 1200° C. and can be in a range of 1200° C. to 3600° C. In the illustrated embodiment, the contact structure 99 comprises copper. The electrically conductive barrier material 61 can comprise at least one of cobalt, tungsten, vanadium, molybdenum, and nickel. In various embodiments, the material of the electrically conductive barrier material 61 can diffuse into the contact structure 99. For example, the contact structure 99 can comprise less than 20%, or less than 15%, of the electrically conductive barrier material 61 during manufacture but then more than 50% as the product is used. As one example, a copper contact structure 99 may contain less than 20%, or less than 15%, cobalt when manufactured, but then the copper contact structure 99 may contain more than 50% cobalt as the product is used. One advantage of the embodiment shown in FIG. 10 over conventional structures (such as those shown in FIG. 4A) is that Co and Ni alloys exhibit superior high temperature properties compared to pure Cu. This makes such materials better suited for high-temperature applications such as in automobiles, switches, and relays, etc.).

In FIG. 10, a thickness 101 of the contact structure 99 can be less than a thickness 63 of the electrically conductive barrier material 61. For example, the thickness 63 of the electrically conductive barrier material 61 can be at least two times the thickness 101 of the contact structure 99. Thus, the bulk of the upper and/or lower conductive layers ( 62 and 100, shown in FIG. 3) comprise second materials with superior high temperature properties and reduced susceptibility to electromigration, whereas the contact structure 99 is provided with a high copper content for superior properties for direct metal bonding, and particularly hybrid direct bonding at comparatively lower temperatures. The skilled artisan will appreciate that the upper contact surface 116 of the contact structure 99 may be recessed below the upper nonconductive surface 114 of the nonconductive layer 56 such that it can expand into metal-metal contact with another contact structure on a different element after the nonconductive materials initially bond, for example forming covalent bonds at room temperature and without application of pressure as disclosed herein. In other words, the contact structure 99 may be recessed below the upper nonconductive surface 114 as a way to prepare the bonding surface 106 for the hybrid direct bonding process detailed above.

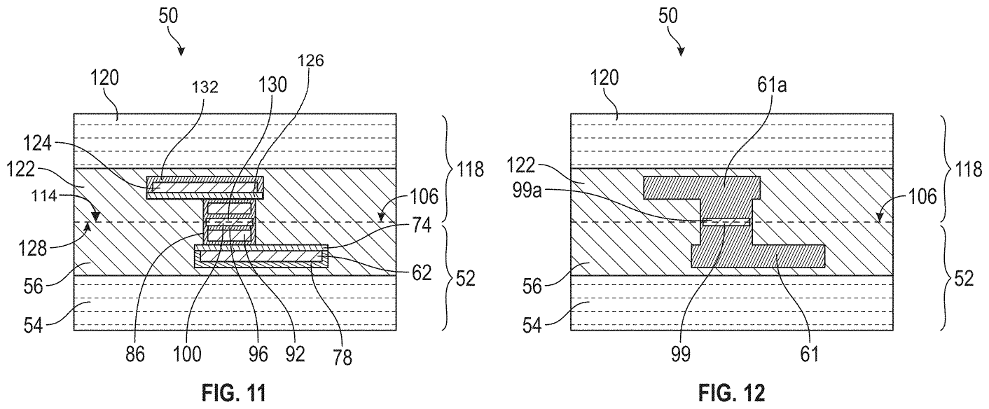

FIG. 11 illustrates a bonded structure 50 in which first and second semiconductor elements 52, 118 are directly hybrid bonded to one another without an adhesive. The first and second semiconductor elements 52, 118 of FIG. 11 can be generally similar to or the same as the semiconductor element 52 shown in FIG. 9E. Both semiconductor elements 52, 118 can have a nonconductive layer 56, 122 on a semiconductor portion 54, 120. Each nonconductive layer 56, 122 can have an upper nonconductive surface 114, 128, and those surfaces can be directly bonded at a bonding surface 106. Furthermore, each semiconductor element 52, 118 can have a lower conductive layer 62, 124 with a first barrier layer 74, 126 lining at least the portion of the lower conductive layer 62, 124 connected to an intermediate conductive layer 92. The lower conductive layers 62, 124 can also be at least partially lined with at least one additional barrier layer (e.g., a lower barrier layer 78, 132). Additionally, the intermediate conductive layer 92 can have a third barrier layer 96 lining at least the portion of the intermediate conductive layer 92 connected to the upper conductive layer 100. The intermediate conductive layer 92 can be at least partially lined on all other side by a second barrier layer 86. And lastly, the upper conductive layer 100 of the first semiconductor element 52 can be directly bonded to the contact structure 130 of the second semiconductor element 118.

FIG. 12 illustrates a bonded structure 50 in which first and second semiconductor elements 52, 118 are directly hybrid bonded to one another without an adhesive. The first and second semiconductor elements 52, 118 of FIG. 12 can be generally similar to or the same as the semiconductor element 52 shown in FIG. 10. Both semiconductor elements 52, 118 can have a nonconductive layer 56, 122 on a semiconductor portion 54, 120. The two semiconductor elements 52, 118 can be directly bonded at a bonding surface 106. The first semiconductor element 52 has a contact structure 99 on an electrically conductive barrier material 61, and the second semiconductor element 118 has a contact structure 99a on an electrically conductive barrier material 61a, as described herein.

FIGS. 13A-13D illustrate another process flow for forming a semiconductor element 52. The method of FIGS. 13A-13D may be generally similar to the method shown in FIGS. 8F-8I. FIG. 13A illustrates a nonconductive layer 56 on a semiconductor portion 54, with a lower conductive layer 62 embedded in the nonconductive layer 56. The lower conductive layer 62 can be encapsulated by a lower barrier layer 78 except for the portion of the lower conductive layer 62 that is going to connect to an upper conductive layer 100 (shown in FIG. 13C-13D), which is lined with a first barrier layer 74. In FIG. 13A, the upper nonconductive surface 114 of the nonconductive layer 56 can be exposed to a plasma 117 to improve adhesion of the second barrier layer 86 to the surrounding dielectric material, such as the nonconductive layer 56 for direct hybrid bonding. In some embodiments, sidewalls of the cavity in the nonconductive layer 56 can also be exposed to the plasma 117 to improve adhesion of the second barrier layer 86. The upper surface of the first barrier layer 74 may also be exposed to the plasma 117. The plasma can comprise a nitrogen- or oxygen-containing (e.g., a water vapor plasma) plasma in various embodiments. In FIG. 13B, a second barrier layer 86 can be provided on the nonconductive layer 56. Although FIG. 13B illustrates a bottomless second barrier layer 86, the skilled artisan will appreciate that the second barrier layer 86 can alternatively cover the first barrier layer 74. In FIG. 13C, a contact structure (e.g., an upper conductive layer 100) can be disposed on the first and second barrier layers 74, 86. In FIG. 13D, the excess metal (e.g., copper) of the upper conductive layer 100 can be removed with a planarization process. In FIG. 13D, the planarization process can remove all excess metal from the upper conductive layer 100 but stop on the second barrier layer 86, thus not exposing the nonconductive layer 56 beneath the second barrier layer 86. The resulting bonding surface 106 of the semiconductor element 52 can be ready to be directly bonded to another semiconductor element.

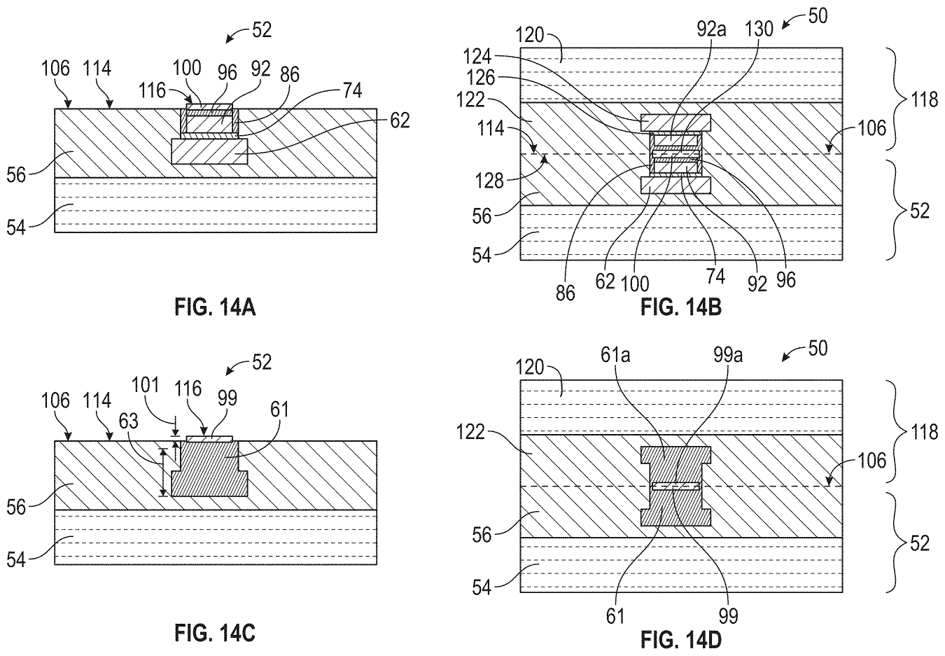

FIGS. 14A and 14C illustrate example semiconductor elements 52 described herein. FIG. 14B illustrates a bonded structure 50 in which two semiconductor elements 52, 118 similar to those of FIG. 14A are directly hybrid bonded to one another. FIG. 14D illustrates a bonded structure 50 in which two semiconductor elements 52, 118 similar to those of FIG. 14C are directly bonded to one another.

FIGS. 14A-14D all illustrate semiconductor elements 52, 118 that can each comprise a nonconductive layer 56, 122 on a semiconductor portion 54, 120. Each semiconductor element can have a bonding surface 106 that comprises a nonconductive portion (e.g., upper nonconductive surfaces 114, 128 of nonconductive layers 56, 122) and a conductive portion (e.g., an upper contact surface 116). Each of the bonded structures 50 in 14B and 14D can be formed by directly hybrid bonding the semiconductor elements 52, 118 together at the bonding surface 106, as described herein.

In FIGS. 14A, the upper contact surface 116 can be a surface of an upper conductive layer 100. As further described herein, the upper conductive layer 100 can be provided on a third barrier layer 96, which can in turn be provided on an intermediate conductive layer 92, which can in turn be provided on a first barrier layer 74, which can in turn be provided on a lower conductive layer 62. Any portion of the intermediate conductive layer 92 not lined with either the first or third barrier layers 74, 96 can be lined with a second barrier layer 86, as described herein. Both semiconductor elements 52, 118 in FIG. 14B can be similar or the same as the one shown in FIG. 14A. Both semiconductor elements 52, 118 can have lower conductive layers 62, 124, first barrier layers 74, 126, intermediate conductive layers 92, 92 a, second barrier layers 86, third barrier layers 96, and a contact structure (e.g., the upper conductive layer 100 of the first semiconductor element 52 and the contact structure 130 of the second semiconductor element 118).

In FIG. 14C, the upper contact surface 116 can be a surface of a contact structure 99. Both semiconductor elements 52, 118 in FIG. 14D can be similar or the same as the one shown in FIG. 14C. Both semiconductor elements 52, 118 can have contact structures 99, 99a (with thickness 101) disposed on an electrically conductive barrier material 61, 61a (with thickness 63).

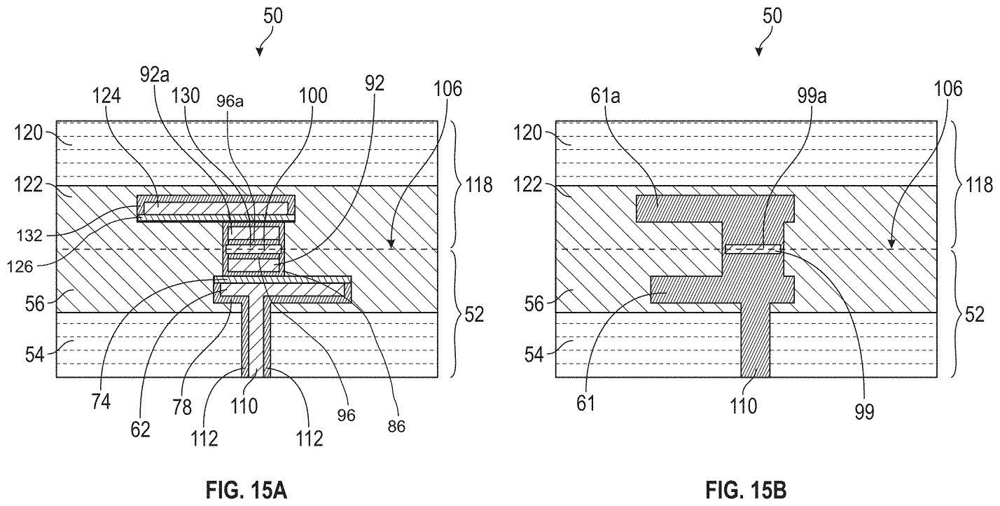

FIGS. 15A and 15B illustrate bonded structures 50 in which at least one semiconductor element 52 of the bonded structure 50 includes a through-substrate via (TSV) 110. Both FIGS. 15A and 15B illustrate bonded structures 50 that can be formed by directly hybrid bonding the semiconductor elements 52, 118 together at the bonding surface 106, as described herein. FIG. 15A is similar to FIG. 11, but the bonded structure 50 shown in FIG. 15A can include a TSV 110 and a TSV barrier 112. FIG. 15B is similar to FIG. 12, but the bonded structure 50 shown in FIG. 15B can include a TSV 110.

Both semiconductor elements 52, 118 in FIG. 15A can include the following as described in FIG. 11: lower barrier layers 78, 132; lower conductive layers 62, 124; first barrier layers 74, 126; intermediate conductive layers 92, 92a; second barrier layers 86; third barrier layers 96, 96a; contact structures (e.g., the upper conductive layer 100 of the first semiconductor element 52 and the contact structure 130 of the second semiconductor element 118); nonconductive layers 56, 122; and semiconductor portions 54, 120. Unlike FIG. 11, however, FIG. 15A shows a TSV 110 and a TSV barrier 112. In FIG. 15A, the TSV 110 can comprise a conductive material (such as copper) electrically connected to the lower conductive layer 62 and extending through the semiconductor portion 54 of the semiconductor element 52. A TSV barrier layer 112 can line the TSV 110. In the illustrated embodiment, the TSV barrier layer 112 can comprise the second material described herein, which can provide high electrical conductivity and reduce or eliminate electromigration failure. Beneficially, using cobalt or nickel alloy as a constituent material of a TSV barrier layer 112 acts as a redundant current pathway and conducting layer.

Both semiconductor elements 52, 118 in FIG. 15B can include the following as described in FIG. 12: contact structures 99, 99a; electrically conductive barrier material 61, 61a; nonconductive layers 56, 122; and semiconductor portions 54, 120. Unlike FIG. 12, however, FIG. 15B shows a TSV 110. In FIG. 15B, the TSV 110 can comprise mostly (e.g., substantially only) the second material.

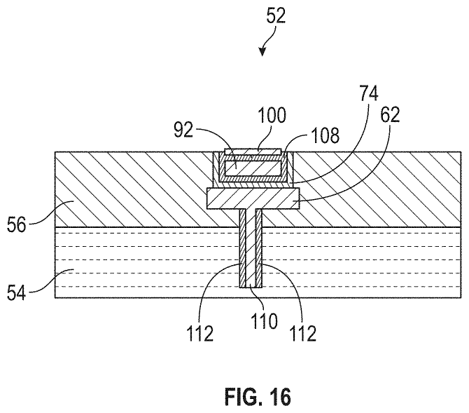

FIG. 16 illustrates another embodiment of a semiconductor element 52 that can include an inner manganese barrier layer 108. Like other embodiments, the semiconductor element 52 in FIG. 16 includes a nonconductive layer 56 on a semiconductor portion 54. Like FIG. 15A, FIG. 16 shows that a lower conductive layer 62 can be embedded in the nonconductive portion 56 and electrically connected to the semiconductor portion 54 by a TSV 110 and a TSV barrier layer 112. In FIG. 16, a barrier layer 74 formed of the second material (e.g., cobalt, cobalt alloys, nickel alloys) can line at least a portion of the lower conductive layer 62 and can extend vertically as far as the upper surface of the nonconductive layer 56. An inner manganese barrier layer 108 can be disposed adjacent the barrier layer 74 formed of the second material. The inner manganese barrier layer 108 can line at least a portion of a cavity in which the contact structure is disposed, with the barrier layer 74 disposed outside the manganese barrier layer 108. Then, disposed in layers within manganese barrier layer 108 can be an intermediate conductive layer 92, more manganese barrier layer 108 material, and an upper conductive layer 100.

At higher bonding temperatures, the manganese barrier layer 108 may alloy with the contact structure (e.g., the upper conductive layer 100 and/or the intermediate conductive layer 92) or the barrier layer 74 or both to improve the electromigration resistance of the semiconductor element 52 after high temperature bonding operations. Apart from Mn, other metals or metal alloys are capable of improving the electromigration resistance of the contact structure (e.g., the upper conductive layer 100), for example indium, gallium, tin and their respective alloys may be applied as the inner barrier layer 108 disposed between the barrier layer 74 and the contact structure (e.g., the upper conductive layer 100 and/or the intermediate conductive layer 92). In some embodiments, the thickness of the inner manganese barrier layer 108 may be thinner than the thickness of the contact structure (e.g., the upper conductive layer 100). Also, in some embodiments, after the high temperature bonding operation, the material of the inner manganese barrier layer 108 may be dispersed between (e.g., diffused into) the contact structure (e.g., the upper conductive layer 100 and/or the intermediate conductive layer 92) and the barrier layer 74.

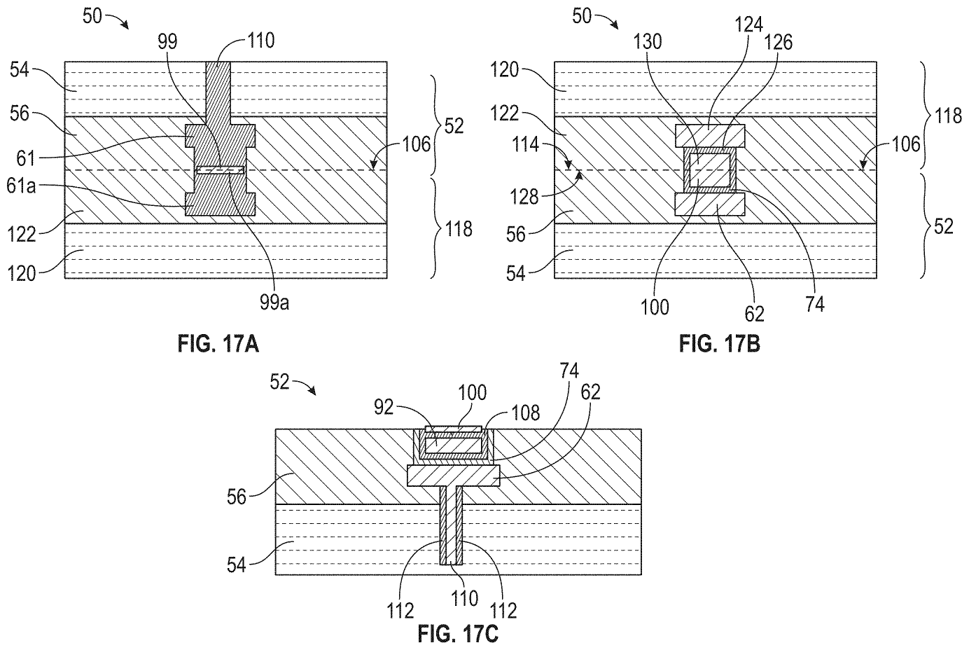

FIGS. 17A illustrates a bonded structure 50 similar to the one illustrated in FIG. 15B. The components can be the same. FIG. 17A looks very similar to FIG. 15B, but FIG. 17A is rotated by 180 degrees. This reinforces that the figures are intended to be illustrative, not limiting. As shown in FIG. 17A, and by way of example, the first semiconductor element 52 can be the one physically above the second semiconductor element 118. This is true for all embodiments disclosed herein.

FIG. 17B illustrates a different embodiment of a bonded structure 50 that can be formed by directly bonding two semiconductor elements 52, 118 along a bonding surface 106. FIG. 17B illustrates a bonded structure 50 similar to FIG. 14B. Each semiconductor element 52, 118 can be the same as the other. Each semiconductor element 52, 118 can have a nonconductive layer 56, 122 on a semiconductor portion 54, 120, and each nonconductive layer 56, 122 can have an upper nonconductive surface 114, 128 along the bonding surface 106. Each semiconductor element 52, 118 has a contact structure (e.g., the upper conductive layer 100 of the first semiconductor element 52 and the contact structure 130 of the second semiconductor element 118) at least partially embedded in the nonconductive layer 56, 122, and with a surface substantially along the bonding surface 106. Except for the portions of the contact structures (e.g., the upper conductive layer 100 of the first semiconductor element 52 and the contact structure 130 of the second semiconductor element 118) along the bonding surface 106, all other surfaces of the contact structures can be lined with a barrier layer 74, 126. Said differently, the barrier layers 74, 126 can line the trenches of the contact structures (e.g., the upper conductive layer 100 of the first semiconductor element 52 and the contact structure 130 of the second semiconductor element 118). These barrier layers 74, 126 can comprise any second material disclosed herein. And lastly, connected to the barrier layers 74, 126 and at least partially embedded in the nonconductive layer 56, 122, each semiconductor element 52, 118 can include a lower conductive layer 62, 124. In this embodiment, as with all the others disclosed herein, the presence of barrier layers 74, 126 that comprise a second material disclosed herein (see Table 1 above) reduces the problems associated with electromigration.

FIG. 17C illustrates a semiconductor element 52 similar to FIG. 16. The semiconductor element 52 can include both an inner manganese barrier layer 108 and a TSV 110 lined with a TSV barrier 112. Beneficially, using cobalt or nickel alloy as a constituent material of a TSV barrier layer 112 acts as a redundant current pathway and conducting layer. In some embodiments, the second material of the barrier layer 74 can comprise a nickel vanadium (NiV) alloy with up to 20% vanadium, e.g., in a range of 0.01% to 5% vanadium. In some embodiments, the second material of the barrier layer 74 can comprise Cu/Fe for radiation hardness. In some embodiments, the second material of the barrier layer 74 can include a bimetallic redundant barrier, including materials such as vanadium, chromium, manganese, iron, and/or nickel (for example, a Mn/Co bimetallic redundant barrier structure).

### SUMMARY

In one embodiment, a semiconductor element can include a semiconductor portion; a nonconductive layer; an upper conductive layer at least partially embedded in the nonconductive layer, the upper conductive layer formed of a first material; a lower conductive layer below and electrically connected to the upper conductive layer; and a barrier layer disposed between the upper conductive layer and the lower conductive layer, the barrier layer formed of a second material different from the first material, the second material having an electrical resistivity less than 50×10⁻⁸ mΩ at 20° C. and a melting point greater than 1200° C.

In some embodiments, the first material comprises copper. In some embodiments, the lower conductive layer comprises copper. In some embodiments, the second material comprises at least one of cobalt, tungsten, vanadium, molybdenum, and nickel. In some embodiments, the second material comprises cobalt. In some embodiments, the second material comprises an alloy. In some embodiments, the alloy comprises at least one of cobalt tungsten phosphate (CWP), cobalt phosphate (CoP), nickel phosphate (NiP), nickel tungsten (NiW), and nickel vanadium (NiV). In some embodiments, the electrical resistivity of the second material is in a range of 4.5×10⁻⁸ mΩ at 20° C. to 30×10⁻⁸ mΩ at 20° C. In some embodiments, the melting point of the second material is in a range of 1200° C. to 3600° C. In some embodiments, the nonconductive layer comprises silicon oxide. In some embodiments, the barrier layer lines at least a portion of a cavity in which the upper conductive layer is disposed. In some embodiments, the semiconductor element can include a second barrier layer lining at least a portion of a cavity in which the upper conductive layer is disposed, the second barrier layer disposed between the barrier layer and the upper conductive layer. In some embodiments, the second barrier layer comprises the second material. In some embodiments, the second barrier layer comprises a third material different from the first material and the second material. In some embodiments, the third material comprises a metal nitride. In some embodiments, the third material comprises titanium nitride or tantalum nitride. In some embodiments, a thickness of the barrier layer is greater than a thickness of the second barrier layer. In some embodiments, the semiconductor element can include an intermediate conductive layer over the barrier layer and a third barrier layer over the intermediate conductive layer, the upper conductive layer disposed over the third barrier layer. In some embodiments, the intermediate conductive layer is encapsulated by the third barrier layer and one or more additional barrier layers. In some embodiments, the one or more additional barrier layers comprises the barrier layer. In some embodiments, the third barrier layer comprises the second material. In some embodiments, the barrier layer lines a cavity in which the intermediate conductive layer is disposed, the barrier layer extending vertically above the third barrier layer substantially to the bonding surface. In some embodiments, a thickness of the upper conductive layer is less than a thickness of the second conductive layer. In some embodiments, the lower conductive layer comprises a redistribution layer (RDL) embedded in the nonconductive layer. In some embodiments, the nonconductive layer comprises a plurality of dielectric layers disposed on the semiconductor portion. In some embodiments, the semiconductor element can include a manganese barrier layer disposed adjacent the barrier layer. In some embodiments, the manganese barrier layer lines at least a portion of a cavity in which the upper conductive layer is disposed, the manganese barrier layer disposed inside the barrier layer. In some embodiments, the barrier layer is disposed along a length of an upper surface of the lower conductive layer, the length being greater than a width of the upper conductive layer. In some embodiments, the lower conductive layer is encapsulated by the barrier layer along the upper surface and by one or more additional barrier layers along a lower surface and side surface(s) of the lower conductive layer. In some embodiments, the one or more additional barrier layers comprise the second material. In some embodiments, the one or more additional barrier layers comprise a third material different from the first and second materials. In some embodiments, the semiconductor element can include a through substrate via (TSV) connected to the lower conductive layer and extending through the semiconductor portion. In some embodiments, the semiconductor element can include a TSV barrier layer that lines the TSV, the TSV barrier layer comprising the second material. In some embodiments, the upper conductive layer comprises a dual damascene structure. In some embodiments, the upper conductive layer comprises a single damascene structure.

In some embodiments, a bonded structure can include the semiconductor element and a second semiconductor element, an upper nonconductive surface of the semiconductor element directly bonded to a second upper nonconductive surface of the second semiconductor element without an intervening adhesive, an upper contact surface of the upper conductive layer directly bonded to a contact structure of the second semiconductor element. In some embodiments, the second semiconductor element comprises: a second semiconductor portion; a second nonconductive layer on the second semiconductor portion and forming the second upper nonconductive surface, the contact structure at least partially embedded in the second nonconductive layer; a second lower conductive layer below and electrically connected to the contact structure; and a first barrier layer of the second semiconductor element disposed between the contact structure and the second lower conductive layer, the first barrier layer of the second semiconductor element formed of a material having an electrical resistivity less than 30×10⁻⁸ mΩ at 20° C. and a melting point greater than 1200° C. In some embodiments, the contact structure comprises copper and the material of the first barrier layer of the second semiconductor element comprises at least one of cobalt, tungsten, vanadium, and nickel.

In another embodiment, a semiconductor element can include a semiconductor portion; a nonconductive bonding layer on the semiconductor portion having an upper nonconductive surface forming a first portion of a bonding surface of the semiconductor element, the upper nonconductive surface prepared for direct bonding to another semiconductor element; a contact structure at least partially embedded in the nonconductive bonding layer and having an upper contact surface forming a second portion of the bonding surface of the semiconductor element, the contact structure comprising a first material; a conductive layer below and electrically connected to the contact structure; and a barrier layer disposed between the contact structure and the conductive layer, the barrier layer comprising a second material different from the first material, the second material including at least one of cobalt, tungsten, vanadium, and nickel.

In some embodiments, the contact structure comprises copper. In some embodiments, the conductive layer comprises copper. In some embodiments, the barrier layer comprises cobalt. In some embodiments, the barrier layer comprises an alloy. In some embodiments, the alloy comprises at least one of cobalt tungsten phosphate (CWP), cobalt phosphate (CoP), nickel phosphate (NiP), nickel tungsten (NiW), and nickel vanadium (NiV). In some embodiments, the nonconductive bonding layer comprises silicon oxide. In some embodiments, the barrier layer lines at least a portion of a cavity in which the contact structure is disposed. In some embodiments, the semiconductor element can include a second barrier layer lining at least a portion of a cavity in which the contact structure is disposed, the second barrier layer disposed between the barrier layer and the contact structure. In some embodiments, the second barrier layer comprises the second material. In some embodiments, the second barrier layer comprises a third material different from the first material and the second material. In some embodiments, the third material comprises a metal nitride. In some embodiments, the third material comprises titanium nitride or tantalum nitride. In some embodiments, a thickness of the barrier layer is greater than a thickness of the second barrier layer. In some embodiments, the semiconductor element can include a second conductive layer over the barrier layer and a third barrier layer over the second conductive layer, the contact structure disposed over the third barrier layer. In some embodiments, the second conductive layer is encapsulated by the third barrier layer and one or more additional barrier layers. In some embodiments, the one or more additional barrier layers comprises the barrier layer. In some embodiments, the third barrier layer comprises the second material. In some embodiments, the barrier layer lines a cavity in which the second conductive layer is disposed, the barrier layer extending vertically above the third barrier layer substantially to the bonding surface. In some embodiments, a thickness of the contact structure is less than a thickness of the second conductive layer. In some embodiments, the conductive layer comprises a redistribution layer (RDL) embedded in the nonconductive bonding layer. In some embodiments, the nonconductive bonding layer comprises a plurality of dielectric layers disposed on the semiconductor portion. In some embodiments, the semiconductor element can include a manganese barrier layer disposed adjacent the barrier layer. In some embodiments, the manganese barrier layer lines at least a portion of a cavity in which the contact structure is disposed, the manganese barrier layer disposed inside the barrier layer. In some embodiments, the barrier layer is disposed along a length of an upper surface of the conductive layer, the length being greater than a width of the contact structure. In some embodiments, the conductive layer is encapsulated by the barrier layer along the upper surface and by one or more additional barrier layers along a lower surface and side surface(s) of the conductive layer. In some embodiments, the one or more additional barrier layers comprise the second material. In some embodiments, the one or more additional barrier layers comprise a third material different from the first and second materials. In some embodiments, the semiconductor element can include a through-substrate via (TSV) electrically connected to the conductive layer and extending through the semiconductor portion. In some embodiments, the semiconductor element can include a TSV barrier layer that lines the TSV, the TSV barrier layer comprising the second material. In some embodiments, the contact structure comprises a dual damascene structure. In some embodiments, the contact structure comprises a single damascene structure.

In some embodiments, a bonded structure can include the semiconductor element and the second semiconductor element, the upper nonconductive surface of the semiconductor element directly bonded to a second upper nonconductive surface of the second semiconductor element without an intervening adhesive, the upper contact surface of the contact structure directly bonded to a second contact structure of the second semiconductor element. In some embodiments, the second semiconductor element comprises: a second semiconductor portion; a second nonconductive bonding layer on the second semiconductor portion and forming the second upper nonconductive surface, the second contact structure at least partially embedded in the second nonconductive bonding layer; a second conductive layer below and electrically connected to the second contact structure; and a first barrier layer of the second semiconductor element disposed between the second contact structure and the second conductive layer, the first barrier layer of the second semiconductor element formed of a material having an electrical resistivity less than 30×10⁻⁸ mΩ at 20° C. and a melting point greater than 1200° C. In some embodiments, the second contact structure comprises copper and the material of the first barrier layer of the second semiconductor element comprises at least one of cobalt, tungsten, vanadium, and nickel.

In another embodiment, a semiconductor element can include a semiconductor portion; a nonconductive layer on the semiconductor portion; a contact structure at least partially embedded in the nonconductive bonding layer and having an upper contact surface forming at least a portion of a bonding surface of the semiconductor element, the contact structure comprising a first material; a conductive layer below and electrically connected to the contact structure; and one or more barrier layers encapsulating the conductive layer, the one or more barrier layers disposed around upper, lower, and side surfaces of the conductive layer.

In some embodiments, the contact structure comprises copper. In some embodiments, the conductive layer comprises copper. In some embodiments, the one or more barrier layers comprises a first barrier layer disposed along a length of the upper surface of the conductive layer, the length being greater than a width of the contact structure, the barrier layer comprising a second material different from the first material. In some embodiments, the second material comprises at least one of cobalt, tungsten, vanadium, and nickel. In some embodiments, the second material has an electrical resistivity less than 30×10⁻⁸ mΩ at 20° C. and a melting point greater than 1200° C. In some embodiments, the one or more barrier layers comprises a second barrier layer disposed along the lower and side surfaces of the conductive layer. In some embodiments, the second barrier layer comprises the second material. In some embodiments, the second barrier layer comprises a third material different from the second material. In some embodiments, the third material comprises a metal nitride. In some embodiments, the third material comprises titanium nitride or tantalum nitride. In some embodiments, the semiconductor element can include a second conductive layer over the one or more barrier layers and a third barrier layer over the second conductive layer, the contact structure disposed over the third barrier layer. In some embodiments, the second conductive layer is encapsulated by the third barrier layer and one or more additional barrier layers. In some embodiments, the third barrier layer comprises the second material. In some embodiments, a thickness of the contact structure is less than a thickness of the second conductive layer. In some embodiments, the conductive layer comprises a redistribution layer (RDL) embedded in the nonconductive bonding layer.

In another embodiment, a semiconductor element can include a semiconductor portion having an upper nonconductive surface forming a first portion of a bonding surface of the semiconductor element, the upper nonconductive surface prepared for direct bonding to a second semiconductor element; a contact structure having an upper contact surface forming a second portion of the bonding surface of the semiconductor element, the contact structure formed of a first material; and an electrically conductive barrier material below and electrically connected to the contact structure, the electrically conductive barrier material comprising a second material different from the first material, the second material having an electrical resistivity less than 30×10⁻⁸ mΩ at 20° C. and a melting point greater than 1200° C.

In some embodiments, the contact structure comprises copper. In some embodiments, the contact structure comprises less than 20% of the electrically conductive barrier material. In some embodiments, the second material comprises at least one of cobalt, tungsten, vanadium, and nickel. In some embodiments, the second material comprises cobalt. In some embodiments, the electrical resistivity of the second material is in a range of 4.5×10⁻⁸ mΩ at 20° C. to 30×10⁻⁸ mΩ at 20° C. In some embodiments, the melting point of the second material is in a range of 1200° C. to 3600° C. In some embodiments, a thickness of the contact structure is less than a thickness of the electrically conductive barrier material. In some embodiments, the thickness of the electrically conductive barrier material is at least two times the thickness of the contact structure.

In another embodiment, a method can include forming a cavity in a nonconductive layer of a semiconductor element; providing a lower conductive layer in the cavity; providing a barrier layer over the lower conductive layer; and providing an upper conductive layer over the barrier layer, the upper conductive layer formed of a first material and the barrier layer formed of a second material different from the first material, the second material having an electrical resistivity less than 30×10⁻⁸ mΩ at 20° C. and a melting point greater than 1200° C.

In some embodiments, the first material comprises copper and the second material comprises at least one of cobalt, tungsten, vanadium, and nickel. In some embodiments, providing the barrier layer comprises providing the barrier layer along a length of an upper surface of the lower conductive layer, the length greater than a width of the contact structure. In some embodiments, the method can include encapsulating the lower conductive layer with the barrier layer and one or more additional barrier layers. In some embodiments, the method can include, before providing the upper conductive layer, forming a second nonconductive layer over the barrier layer and at least a portion of the nonconductive layer and forming an opening in the second nonconductive layer that extends to the barrier layer. In some embodiments, the method can include providing a second barrier layer in the opening over at least a portion of the barrier layer. In some embodiments, providing the second barrier layer comprises providing the second barrier layer formed of the second material. In some embodiments, the method can include providing an intermediate conductive layer in the opening over the second barrier layer. In some embodiments, the method can include providing a third barrier layer over the intermediate conductive layer. In some embodiments, providing the third barrier layer comprises providing the third barrier layer formed of the second material. In some embodiments, the method can include providing the upper conductive layer over the third barrier layer. In some embodiments, the method can include plasma treating an upper surface of the second nonconductive layer. In some embodiments, plasma treating comprises exposing the second nonconductive layer to a plasma comprising nitrogen or oxygen. In some embodiments, the method can include directly bonding the upper conductive layer of the semiconductor element to a contact structure of a second semiconductor element without an intervening adhesive. In some embodiments, the method can include directly bonding a nonconductive bonding layer of the semiconductor element to a second nonconductive bonding layer of the second semiconductor element. In some embodiments, the nonconductive bonding layer comprises the nonconductive layer.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. A semiconductor element comprising:
a semiconductor portion;
a nonconductive layer on the semiconductor portion;
an upper conductive layer at least partially embedded in a cavity of the nonconductive layer, the upper conductive layer formed of a first material;
a lower conductive layer below and electrically connected to the upper conductive layer; and
a barrier layer disposed between the upper conductive layer and the lower conductive layer, the barrier layer laterally wider than the cavity, the barrier layer formed of a second material different from the first material, the second material having an electrical resistivity less than 50×10⁻⁸ mΩ at 20° C. and a melting point greater than 1200° C.

2. (canceled)

3. (canceled)

4. The semiconductor element of claim 1, wherein the second material comprises at least one of cobalt, tungsten, vanadium, molybdenum, or nickel.

5. (canceled)

6. (canceled)

7. (canceled)

8. The semiconductor element of claim 4, wherein the electrical resistivity of the second material is in a range of 4.5×10⁻⁸ mΩ at 20° C. to 30×10⁻⁸ mΩ at 20° C.

9. The semiconductor element of claim 8, wherein the melting point of the second material is in a range of 1200° C. to 3600° C.

10. (canceled)

11. (canceled)

12. The semiconductor element of claim 1, further comprising a second barrier layer lining at least a portion of a cavity in which the upper conductive layer is disposed, the second barrier layer disposed between the barrier layer and the upper conductive layer.

13. The semiconductor element of claim 12, wherein the second barrier layer comprises the second material.

14. The semiconductor element of claim 12, wherein the second barrier layer comprises a third material different from the first material and the second material.

15. (canceled)

16. (canceled)

17. The semiconductor element of claim 12, wherein a thickness of the barrier layer is greater than a thickness of the second barrier layer.

18. (canceled)

19. (canceled)

20. (canceled)

21. (canceled)

22. (canceled)

23. The semiconductor element of claim 1, wherein a thickness of the upper conductive layer is less than a thickness of the lower conductive layer.

24. (canceled)

25. (canceled)

26. (canceled)

27. (canceled)

28. The semiconductor element of claim 1, wherein the barrier layer is disposed along a length of an upper surface of the lower conductive layer, the length being greater than a width of the upper conductive layer.

29. (canceled)

30. (canceled)

31. (canceled)

32. (canceled)

33. (canceled)

34. (canceled)

35. (canceled)

36. A bonded structure comprising the semiconductor element of claim 1 and a second semiconductor element, an upper nonconductive surface of the semiconductor element directly bonded to a second upper nonconductive surface of the second semiconductor element without an intervening adhesive, an upper contact surface of the upper conductive layer directly bonded to a contact structure of the second semiconductor element.

37. The bonded structure of claim 36, wherein the second semiconductor element comprises:
a second semiconductor portion;
a second nonconductive layer on the second semiconductor portion and forming the second upper nonconductive surface, the contact structure at least partially embedded in the second nonconductive layer;
a second lower conductive layer below and electrically connected to the contact structure; and
a first barrier layer of the second semiconductor element disposed between the contact structure and the second lower conductive layer, the first barrier layer of the second semiconductor element formed of a material having an electrical resistivity less than 30×10⁻⁸ mΩ at 20° C. and a melting point greater than 1200° C.

38. The bonded structure of claim 37, wherein the contact structure comprises copper and the material of the first barrier layer of the second semiconductor element comprises at least one of cobalt, tungsten, vanadium, or nickel.

39-89. (canceled)

90. A semiconductor element comprising:
a semiconductor portion having an upper nonconductive surface forming a first portion of a bonding surface of the semiconductor element, the upper nonconductive surface prepared for direct bonding to a second semiconductor element;
a contact structure having an upper contact surface forming a second portion of the bonding surface of the semiconductor element, the contact structure formed of a first material; and
an electrically conductive barrier material below and electrically connected to the contact structure, the electrically conductive barrier material comprising a second material different from the first material, the second material having an electrical resistivity less than 30×10⁻⁸ mΩ at 20° C. and a melting point greater than 1200° C.

91. The semiconductor element of claim 90, wherein the contact structure comprises copper, and wherein the contact structure comprises less than 20% of the electrically conductive barrier material.

92. (canceled)

93. The semiconductor element of claim 90, wherein the second material comprises at least one of cobalt, tungsten, vanadium, or nickel.

94. (canceled)

95. The semiconductor element of claim 90, wherein the electrical resistivity of the second material is in a range of 4.5×10⁻⁸ mΩ at 20° C. to 30×10⁻⁸ mΩ at 20° C., and wherein the melting point of the second material is in a range of 1200° C. to 3600° C.

96. (canceled)

97. (canceled)

98. The semiconductor element of claim 90, wherein a thickness of the electrically conductive barrier material is at least two times a thickness of the contact structure.

99-116. (canceled)

117. A semiconductor element comprising:
a semiconductor portion;
a nonconductive layer on the semiconductor portion;
an upper conductive layer at least partially embedded in the nonconductive layer, the upper conductive layer formed of a first material;
a lower conductive layer below and electrically connected to the upper conductive layer;
a barrier layer disposed between the upper conductive layer and the lower conductive layer, the barrier layer formed of a second material different from the first material, the second material having an electrical resistivity less than 50×10⁻⁸ mΩ at 20° C. and a melting point greater than 1200° C.; and
a second barrier layer lining at least a portion of a cavity in which the upper conductive layer is disposed.

118. The semiconductor element of claim 117, wherein the second barrier layer is disposed between the barrier layer and the upper conductive layer.
